(19) United States
(12) Patent Application Publication
(10) Pub. No.: US 2026/0135526 A1
(43) Pub. Date: May 14, 2026

(54) WAKE ON AUDIO TRIGGER FOR AMPLIFIER OR PLAYBACK DEVICE

(71) Applicant: Sonos Inc., Goleta, CA (US)

(72) Inventor: Mark Gregory Belding, Goleta, CA (US)

(21) Appl. No.: 19/384,246

(22) Filed: Nov. 10, 2025

Related U.S. Application Data
(60) Provisional application No. 63/720,266, filed on Nov. 14, 2024.

(51) Int. Cl. H03F 3/183; H04R 3/04

(52) U.S. Cl. CPC H03F 3/183; H04R 3/04; H03F 2200/03

(57) ABSTRACT

A system for improving power efficiency of an audio amplifier or playback device. The system comprises an analog audio input port, an audio amplifier, and a signal detection circuit. The audio amplifier is configured to transition between a first state and a second state based on a trigger, wherein the audio amplifier consumes less power in the first state than the second state. The audio amplifier is further configured to amplify, when in the second state, an input signal present at the analog audio input port. The signal detection circuit is coupled to the analog audio input port and configured to detect an audio signal present in the input signal and generate the trigger when the audio signal is detected. The trigger is generated based on an integration of the input signal over a period of time to detect that the integrated input signal exceeds a threshold value.

### CROSS-REFERENCE TO RELATED APPLICATIONS

This application claims priority under 35 U.S.C. § 119(e), to co-pending U.S. Provisional Application No. 63/720,266 filed November 14, 2024, titled WAKE ON AUDIO TRIGGER FOR AMPLIFIER OR PLAYBACK DEVICE, which is hereby incorporated herein by reference in its entirety.

### FIELD OF THE DISCLOSURE

The present disclosure is related to consumer goods and, more particularly, to methods, systems, products, features, services, and other elements directed to media playback or some aspect thereof.

### BACKGROUND

Options for accessing and listening to digital audio in an out-loud setting were limited until in 2002, when Sonos, Inc. began development of a new type of playback system. Sonos then filed one of its first patent applications in 2003, entitled “Method for Synchronizing Audio Playback between Multiple Networked Devices,” and began offering its first media playback systems for sale in 2005. The SONOS Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A is a partial cutaway view of an environment having a media playback system configured in accordance with aspects of the disclosed technology.

FIG. 1B is a schematic diagram of the media playback system of FIG. 1A and one or more networks.

FIG. 1C is a block diagram of a playback device.

FIG. 1D is a block diagram of a playback device.

FIG. 1E is a block diagram of a bonded playback device.

FIG. 1F is a block diagram of a network microphone device.

FIG. 1G is a block diagram of a playback device.

FIG. 1H is a partial schematic diagram of a control device.

FIGS. 1I through 1L are schematic diagrams of corresponding media playback system zones.

FIG. 1M is a schematic diagram of media playback system areas.

FIG. 2A is a front isometric view of a playback device configured in accordance with aspects of the disclosed technology.

FIG. 2B is a front isometric view of the playback device of FIG. 2A without a grille.

FIG. 2C is an exploded view of the playback device of FIG. 2A.

FIG. 3A is a front view of a network microphone device configured in accordance with aspects of the disclosed technology.

FIG. 3B is a side isometric view of the network microphone device of FIG. 3A.

FIG. 3C is an exploded view of the network microphone device of FIGS. 3A and 3B.

FIG. 3D is an enlarged view of a portion of FIG. 3B.

FIG. 3E is a block diagram of the network microphone device of FIGS. 3A-3D.

FIG. 3F is a schematic diagram of an example voice input.

FIGS. 4A-4D are schematic diagrams of a control device in various stages of operation in accordance with aspects of the disclosed technology.

FIG. 5 is a front view of a control device.

FIG. 6 is a message flow diagram of a media playback system.

FIG. 7 illustrates an example of an audio playback environment.

FIG. 8 is a block diagram of an example audio amplifier.

FIG. 9 is a block diagram of an example signal detection circuit.

FIG. 10 is a block diagram of another example signal detection circuit.

FIG. 11 is a block diagram of an example playback device.

FIG. 12 is a flowchart illustrating an example method for generating a wake on audio trigger.

The drawings are for the purpose of illustrating example embodiments, but those of ordinary skill in the art will understand that the technology disclosed herein is not limited to the arrangements and/or instrumentality shown in the drawings.

### DETAILED DESCRIPTION

### 1. Overview

SONOS, Inc. has a long history of innovating in the wireless audio space as demonstrated by the successful launch of numerous wireless audio products including, for example, SONOS ROAM, SONOS MOVE, SONOS ERA 100, SONOS ERA 300, SONOS FIVE, SONOS RAY, SONOS BEAM, SONOS ARC, SONOS PORT, and SONOS AMP. Building upon years of experience creating sophisticated, yet easy-to-use, audio products, SONOS, Inc. has appreciated the importance of providing a high quality user experience. This high quality user experience includes energy efficient operation. Energy efficient operation is important to prolong battery life (e.g., in battery operated portable devices) and to reduce the carbon emissions associated with operation of an electronic device over its lifetime (and/or improve the environmental sustainability of the electronic device).

One technique for increasing energy efficiency of an audio device is to allow the device to remain in a lower power or sleep state during periods when there is no audio signal being presented to the device, and then waking the device from that state in response to the detection of an audio signal so that the audio signal can be played back. Audio devices, such as analog audio amplifiers and playback devices, may include audio input ports configured to accept analog input signals. One straightforward method for triggering a transition from a sleep state to an awake state is to detect that a cable has been plugged into the audio input port. Often times, however, a cable is plugged into the port once during setup and remains connected whether or not the system is in use (e.g., whether or not audio is actually being presented at the audio input port). A better technique would be to detect that a signal is present at the audio input port. However, even if a signal is present, it may not be an audio signal. For example, the signal could be noise or a non-audio signal that is not of interest from an audio playback perspective.

To this end, embodiments described herein relate to techniques for detecting the presence of an audio signal at the analog input port of a device (e.g., an analog amplifier or playback device) and using that detection to generate a trigger to wake the device. The wake trigger may then cause the device to transition from the lower power consuming sleep state to the operational awake state. In some examples the detection of an audio signal may be accomplished by integrating the input signal over a period of time and detecting that the integrated input signal exceeds a threshold value. In some examples, the integration is performed on a portion of the input signal that exceeds a first threshold value over a period of time, and the trigger is generated by detecting that the integrated portion of the input signal exceeds a second threshold value, as will be described in greater detail below. In some examples, a filter may be applied to the input signal, prior to integration, to remove or reduce noise and other signal types that occur at frequencies above or outside of the audio frequency band (e.g., the range of frequencies that are audible to human listeners).

While some examples described herein may refer to functions performed by given actors such as “users,” “listeners,” and/or other entities, it should be understood that such references are for purposes of explanation only. The claims should not be interpreted to require action by any such example actor unless explicitly required by the language of the claims themselves.

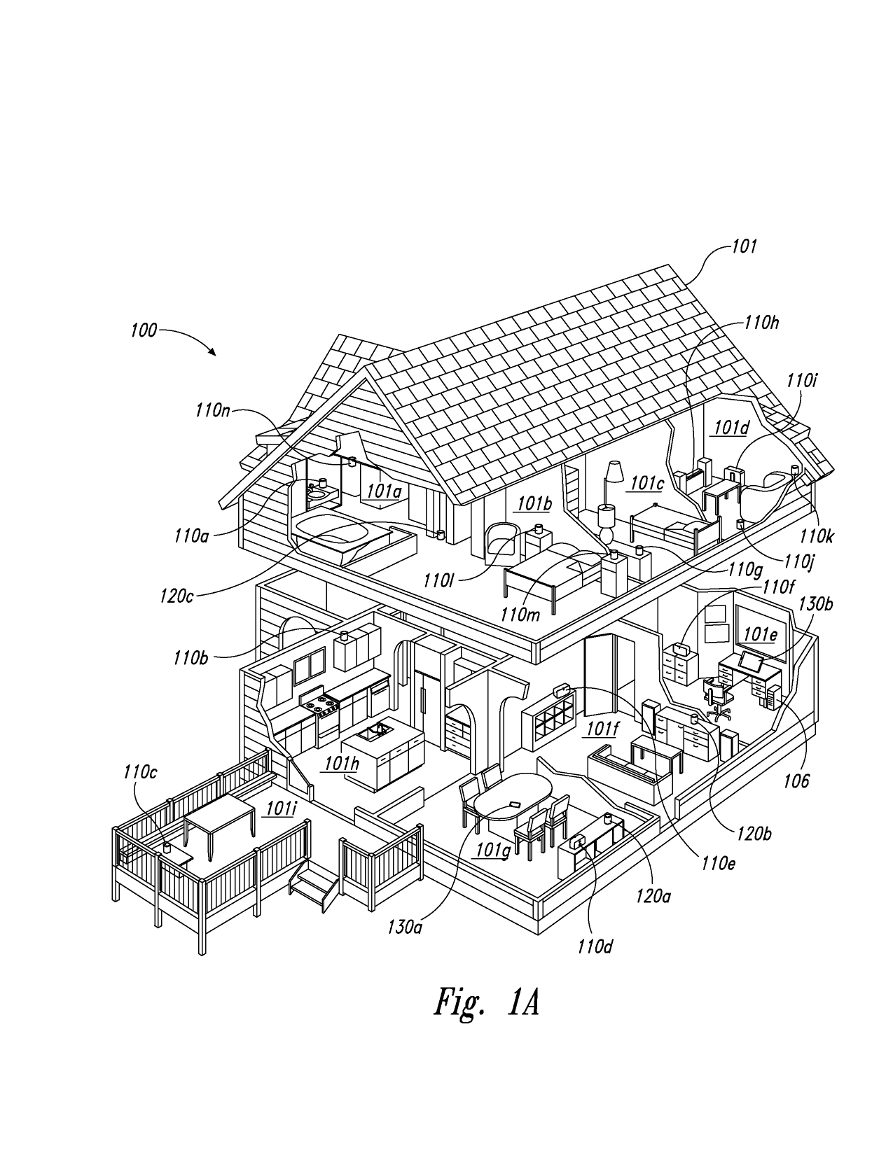

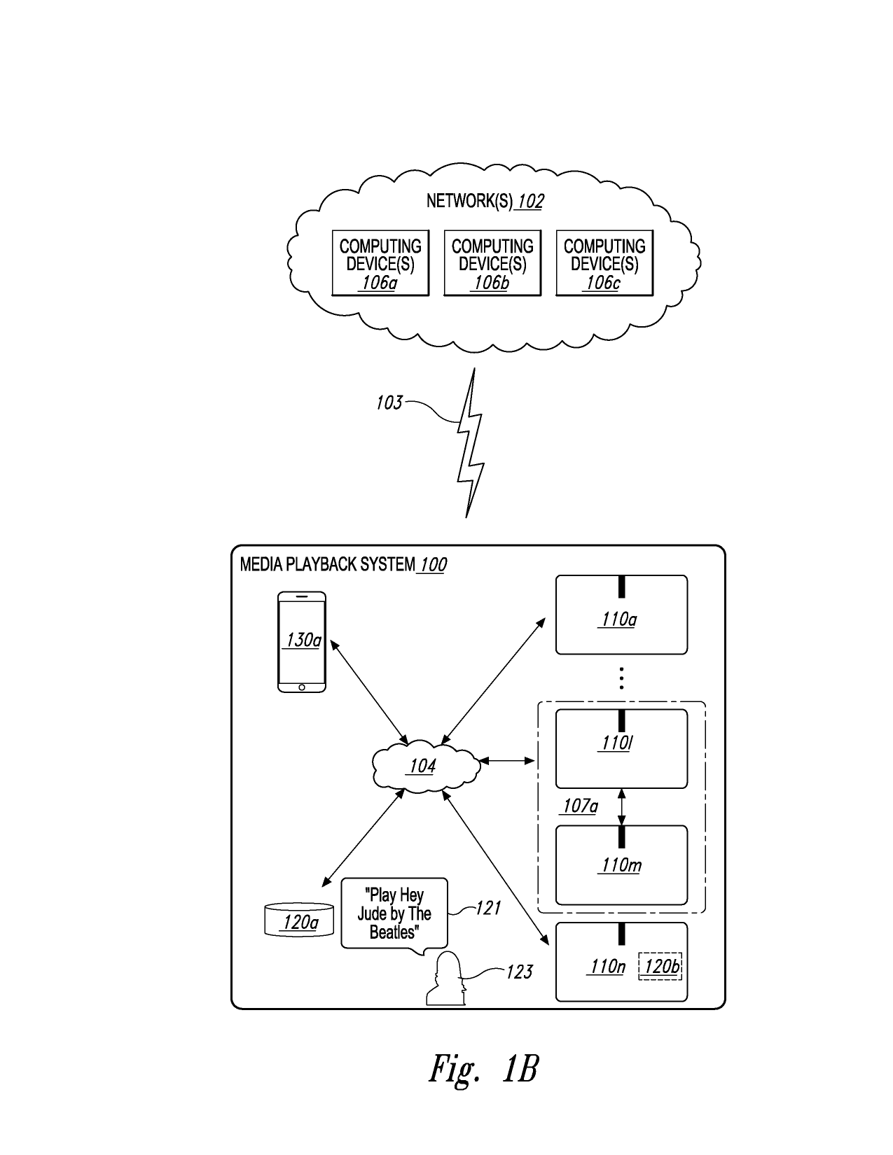

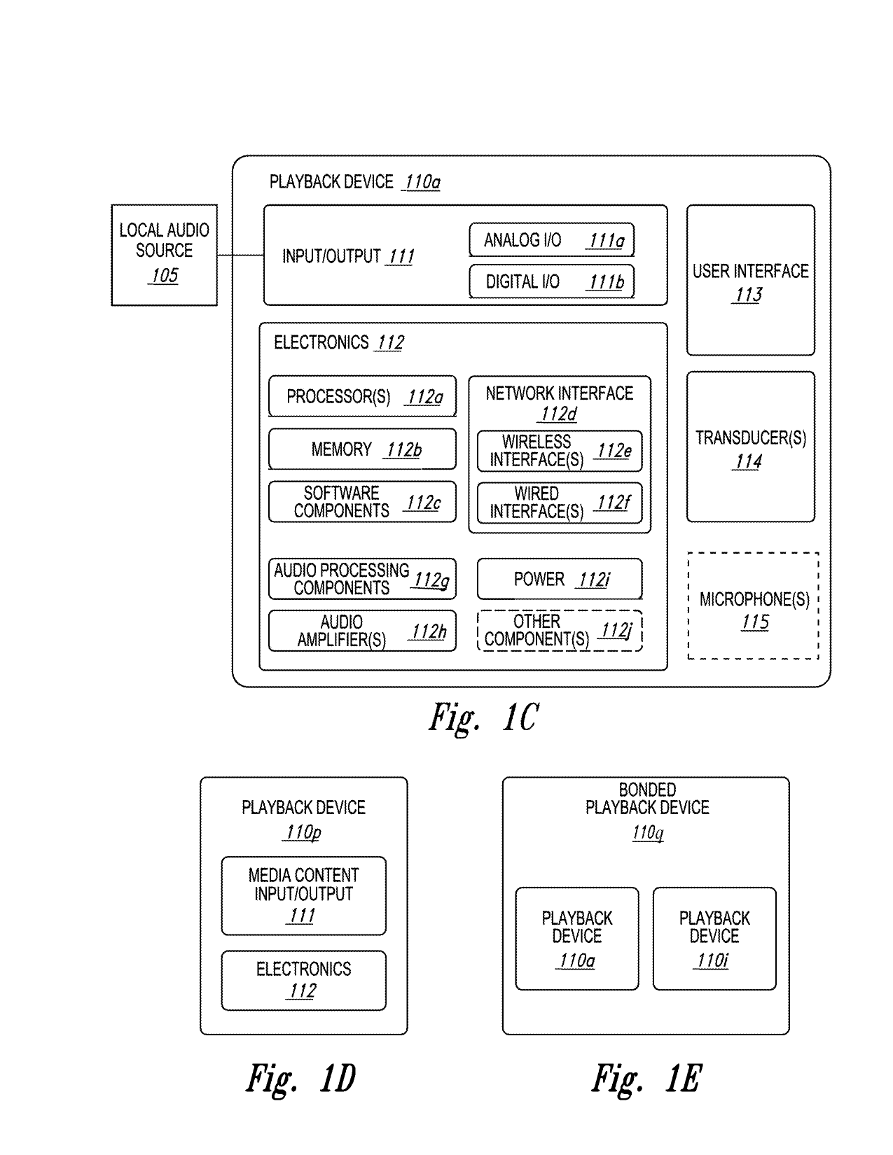

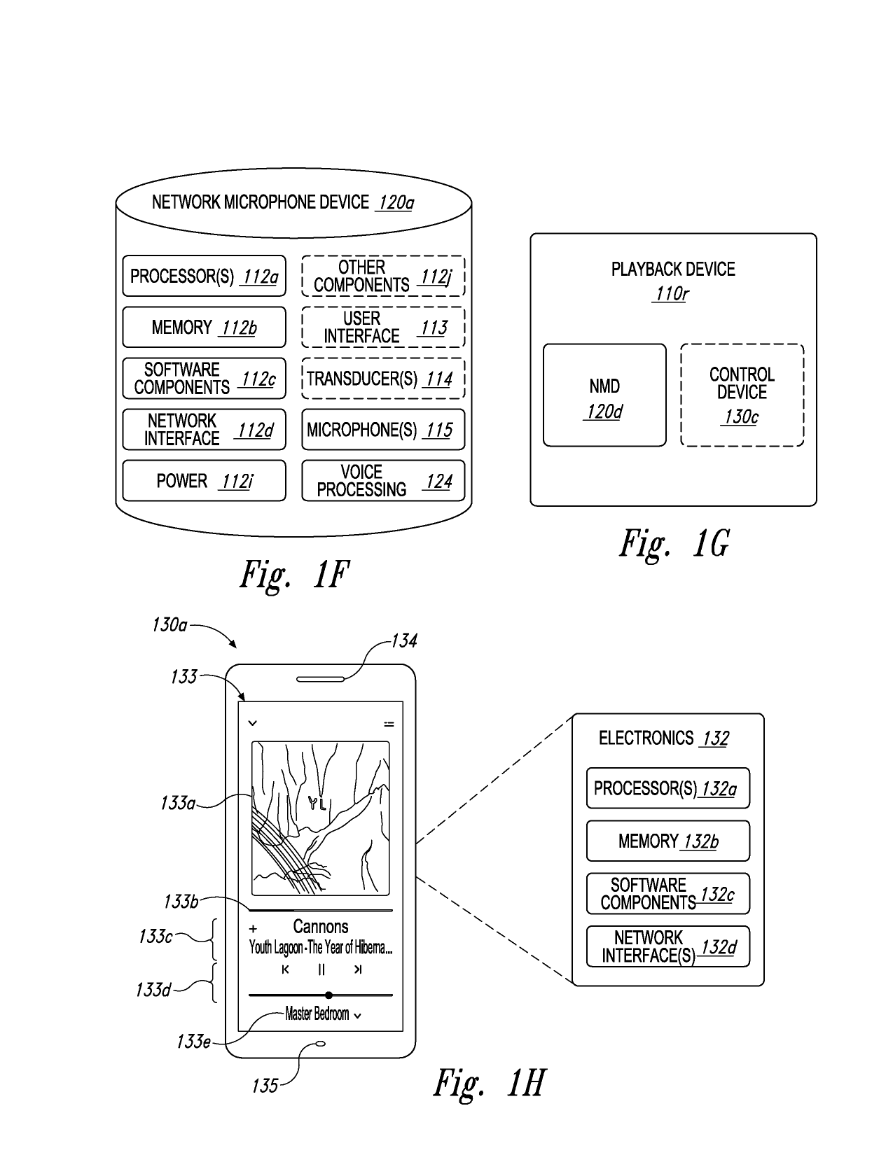

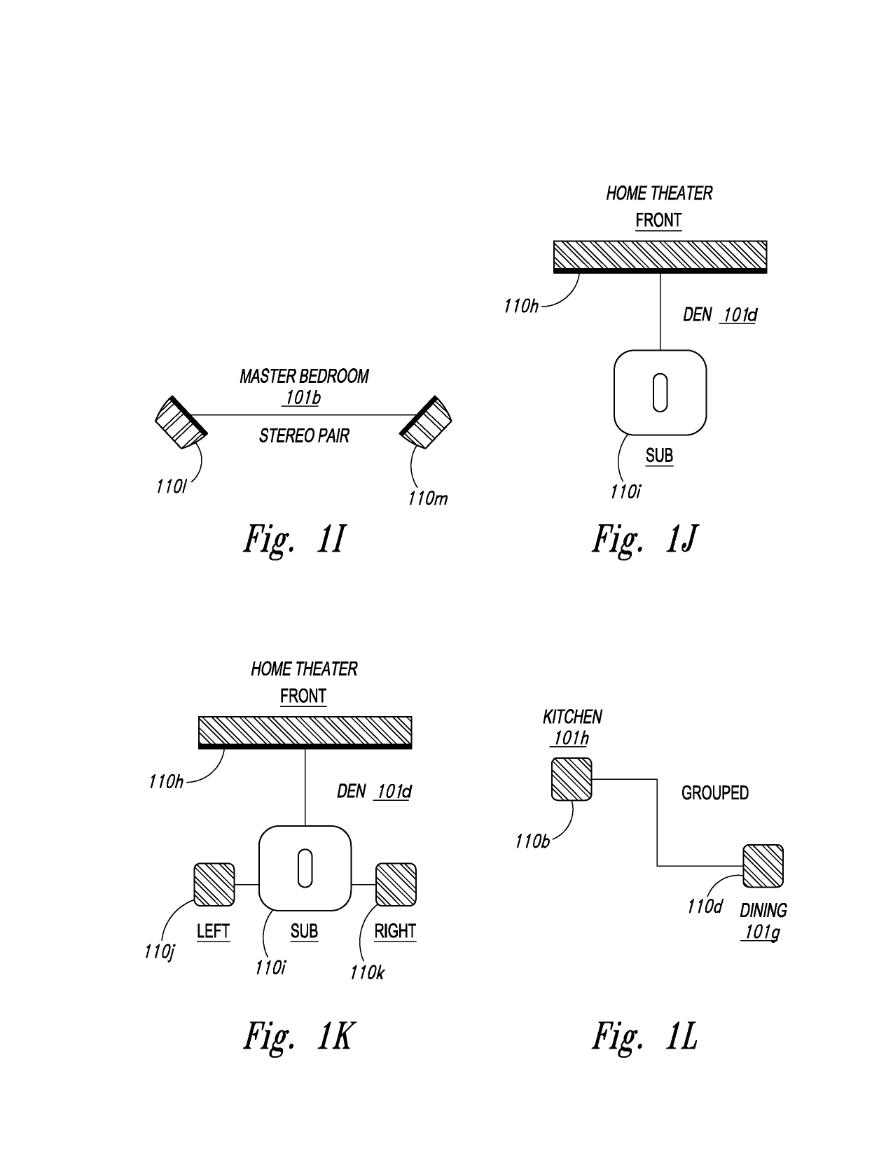

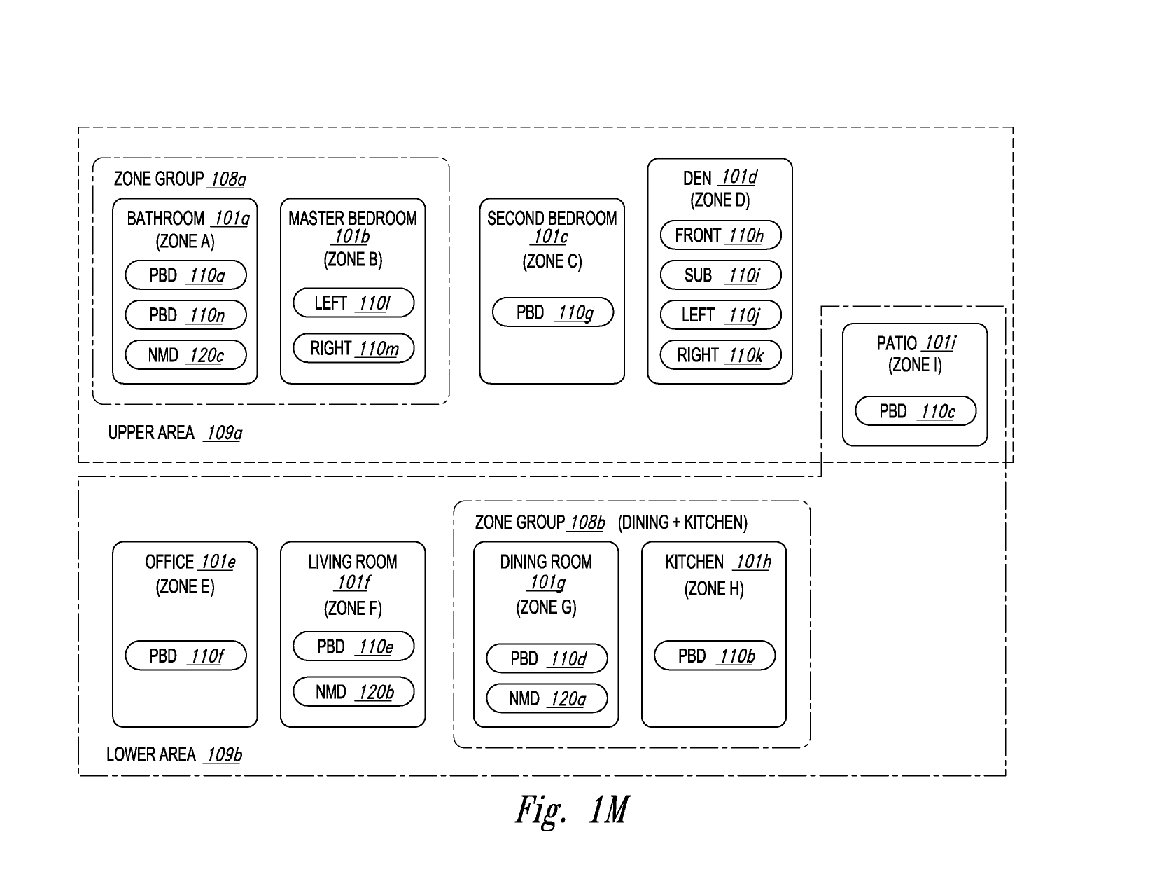

In the Figures, identical reference numbers identify generally similar, and/or identical, elements. To facilitate the discussion of any particular element, the most significant digit or digits of a reference number refers to the Figure in which that element is first introduced. For example, element 110a is first introduced and discussed with reference to FIG. 1A. Many of the details, dimensions, angles, and other features shown in the Figures are merely illustrative of particular embodiments of the disclosed technology. Accordingly, other embodiments can have other details, dimensions, angles, and features without departing from the spirit or scope of the disclosure. In addition, those of ordinary skill in the art will appreciate that further embodiments of the various disclosed technologies can be practiced without several of the details described below.

### Suitable Operating Environment

FIG. 1A is a partial cutaway view of a media playback system 100 distributed in an environment 101 (e.g., a house). The media playback system 100 comprises one or more playback devices 110 (identified individually as playback devices 110a-n), one or more network microphone devices 120 (“NMDs”) (identified individually as NMDs 120a-c), and one or more control devices 130 (identified individually as control devices 130a and 130b).

As used herein the term “playback device” can generally refer to a network device configured to receive, process, and output data of a media playback system. For example, a playback device can be a network device that receives and processes audio content. In some embodiments, a playback device includes one or more transducers or speakers powered by one or more amplifiers. In other embodiments, however, a playback device includes one of (or neither of) the speaker and the amplifier. For instance, a playback device can comprise one or more amplifiers configured to drive one or more speakers external to the playback device via a corresponding wire or cable.

Moreover, as used herein the term “NMD” (i.e., a “network microphone device”) can generally refer to a network device that is configured for audio detection. In some embodiments, an NMD is a stand-alone device configured primarily for audio detection. In other embodiments, an NMD is incorporated into a playback device (or vice versa).

The term “control device” can generally refer to a network device configured to perform functions relevant to facilitating user access, control, and/or configuration of the media playback system 100.

Each of the playback devices 110 is configured to receive audio signals or data from one or more media sources (e.g., one or more remote servers, one or more local devices, etc.) and play back the received audio signals or data as sound. The one or more NMDs 120 are configured to receive spoken word commands, and the one or more control devices 130 are configured to receive user input. In response to the received spoken word commands and/or user input, the media playback system 100 can play back audio via one or more of the playback devices 110. In certain embodiments, the playback devices 110 are configured to commence playback of media content in response to a trigger. For instance, one or more of the playback devices 110 can be configured to play back a morning playlist upon detection of an associated trigger condition (e.g., presence of a user in a kitchen, detection of a coffee machine operation, etc.). In some embodiments, for example, the media playback system 100 is configured to play back audio from a first playback device (e.g., the playback device 110a) in synchrony with a second playback device (e.g., the playback device 110b). Interactions between the playback devices 110, NMDs 120, and/or control devices 130 of the media playback system 100 configured in accordance with the various embodiments of the disclosure are described in greater detail below with respect to FIGS. 1B-6.

In the illustrated embodiment of FIG. 1A, the environment 101 comprises a household having several rooms, spaces, and/or playback zones, including (clockwise from upper left) a master bathroom 101a, a master bedroom 101b, a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the media playback system 100 can be implemented in one or more commercial settings (e.g., a restaurant, mall, airport, hotel, a retail or other store), one or more vehicles (e.g., a sports utility vehicle, bus, car, a ship, a boat, an airplane, etc.), multiple environments (e.g., a combination of home and vehicle environments), and/or another suitable environment where multi-zone audio may be desirable.

The media playback system 100 can comprise one or more playback zones, some of which may correspond to the rooms in the environment 101. The media playback system 100 can be established with one or more playback zones, after which additional zones may be added, or removed, to form, for example, the configuration shown in FIG. 1A. Each zone may be given a name according to a different room or space such as the office 101e, master bathroom 101a, master bedroom 101b, the second bedroom 101c, kitchen 101h, dining room 101g, living room 101f, and/or the balcony 101i. In some aspects, a single playback zone may include multiple rooms or spaces. In certain aspects, a single room or space may include multiple playback zones.

In the illustrated embodiment of FIG. 1A, the second bedroom 101c, the office 101e, the living room 101f, the dining room 101g, the kitchen 101h, and the outdoor patio 101i each include one playback device 110, and the master bathroom 101a, the master bedroom 101b, and the den 101d include a plurality of playback devices 110. In the master bedroom 101b, the playback devices 110l and 110m may be configured, for example, to play back audio content in synchrony as individual ones of playback devices 110, as a bonded playback zone, as a consolidated playback device, and/or any combination thereof. Similarly, in the den 101d, the playback devices 110h-k can be configured, for instance, to play back audio content in synchrony as individual ones of playback devices 110, as one or more bonded playback devices, and/or as one or more consolidated playback devices. Additional details regarding bonded and consolidated playback devices are described below with respect to FIGS. 1B, 1E, and 1I-1M.

In some aspects, one or more of the playback zones in the environment 101 may each be playing different audio content. For instance, a user may be grilling on the patio 101i and listening to hip hop music being played by the playback device 110c while another user is preparing food in the kitchen 101h and listening to classical music played by the playback device 110b. In another

example, a playback zone may play the same audio content in synchrony with another playback zone. For instance, the user may be in the office 101e listening to the playback device 110f playing back the same hip hop music being played back by playback device 110c on the patio 101i. In some aspects, the playback devices 110c and 110f play back the hip hop music in synchrony such that the user perceives that the audio content is being played seamlessly (or at least substantially seamlessly) while moving between different playback zones. Additional details regarding audio playback synchronization among playback devices and/or zones can be found, for example, in U.S. Patent No. 8,234,395 entitled, “System and method for synchronizing operations among a plurality of independently clocked digital data processing devices,” which is incorporated herein by reference in its entirety.

### a. Suitable Media Playback System

FIG. 1B is a schematic diagram of the media playback system 100 and a cloud network 102. For ease of illustration, certain devices of the media playback system 100 and the cloud network 102 are omitted from FIG. 1B. One or more communication links 103 (referred to hereinafter as “the links 103”) communicatively couple the media playback system 100 and the cloud network 102.

The links 103 can comprise, for example, one or more wired networks, one or more wireless networks, one or more wide area networks (WAN), one or more local area networks (LAN), one or more personal area networks (PAN), one or more telecommunication networks (e.g., one or more Global System for Mobiles (GSM) networks, Code Division Multiple Access (CDMA) networks, Long-Term Evolution (LTE) networks, 5G communication networks, and/or other suitable data transmission protocol networks), etc. The cloud network 102 is configured to deliver media content (e.g., audio content, video content, photographs, social media content, etc.) to the media playback system 100 in response to a request transmitted from the media playback system 100 via the links 103. In some embodiments, the cloud network 102 is further configured to receive data (e.g., voice input data) from the media playback system 100 and correspondingly transmit commands and/or media content to the media playback system 100.

The cloud network 102 comprises computing devices 106 (identified separately as a first computing device 106a, a second computing device 106b, and a third computing device 106c). The computing devices 106 can comprise individual computers or servers, such as, for example, a media streaming service server storing audio and/or other media content, a voice service server, a social media server, a media playback system control server, etc. In some embodiments, one or more of the computing devices 106 comprise modules of a single computer or server. In certain embodiments, one or more of the computing devices 106 comprise one or more modules, computers, and/or servers. Moreover, while the cloud network 102 is described above in the context of a single cloud network, in some embodiments the cloud network 102 comprises a plurality of cloud networks comprising communicatively coupled computing devices. Furthermore, while the cloud network 102 is shown in FIG. 1B as having three of the computing devices 106, in some embodiments, the cloud network 102 comprises fewer (or more than) three computing devices 106.

The media playback system 100 is configured to receive media content from the networks 102 via the links 103. The received media content can comprise, for example, a Uniform Resource Identifier (URI) and/or a Uniform Resource Locator (URL). For instance, in some examples, the media playback system 100 can stream, download, or otherwise obtain data from a URI or a URL corresponding to the received media content. A network 104 communicatively couples the links 103 and at least a portion of the devices (e.g., one or more of the playback devices 110, NMDs 120, and/or control devices 130) of the media playback system 100. The network 104 can include, for example, a wireless network (e.g., a WI-FI network, a BLUETOOTH network, a Z-WAVE network, a ZIGBEE network, and/or other suitable wireless communication protocol network) and/or a wired network (e.g., a network comprising Ethernet, Universal Serial Bus (USB), and/or another suitable wired communication). As those of ordinary skill in the art will appreciate, as used herein, “WI-FI” can refer to several different communication protocols including, for example, Institute of Electrical and Electronics Engineers (IEEE) 802.11a, 802.11b, 802.11g, 802.11n, 802.11ac, 802.11ac, 802.11ad, 802.11af, 802.11ah, 802.11ai, 802.11aj, 802.11aq, 802.11ax, 802.11ay, 802.15, etc. transmitted at 2.4 Gigahertz (GHz), 5 GHz, and/or another suitable frequency.

In some embodiments, the network 104 comprises a dedicated communication network that the media playback system 100 uses to transmit messages between individual devices and/or to transmit media content to and from media content sources (e.g., one or more of the computing devices 106). In certain embodiments, the network 104 is configured to be accessible only to devices in the media playback system 100, thereby reducing interference and competition with other household devices. In other embodiments, however, the network 104 comprises an existing household or commercial facility communication network (e.g., a household or commercial facility WI-FI network). In some embodiments, the links 103 and the network 104 comprise one or more of the same networks. In some aspects, for example, the links 103 and the network 104 comprise a telecommunication network (e.g., an LTE network, a 5G network, etc.). Moreover, in some embodiments, the media playback system 100 is implemented without the network 104, and devices comprising the media playback system 100 can communicate with each other, for example, via one or more direct connections, PANs, telecommunication networks, and/or other suitable communication links. The network 104 may be referred to herein as a “local communication network” to differentiate the network 104 from the cloud network 102 that couples the media playback system 100 to remote devices, such as cloud servers that host cloud services.

In some embodiments, audio content sources may be regularly added or removed from the media playback system 100. In some embodiments, for example, the media playback system 100 performs an indexing of media items when one or more media content sources are updated, added to, and/or removed from the media playback system 100. The media playback system 100 can scan identifiable media items in some or all folders and/or directories accessible to the playback devices 110, and generate or update a media content database comprising metadata (e.g., title, artist, album, track length, etc.) and other associated information (e.g., URIs, URLs, etc.) for each identifiable media item found. In some embodiments, for example, the media content database is stored on one or more of the playback devices 110, network microphone devices 120, and/or control devices 130.

In the illustrated embodiment of FIG. 1B, the playback devices 110l and 110m comprise a group 107a. The playback devices 110l and 110m can be positioned in different rooms and be grouped together in the group 107a on a temporary or permanent basis based on user input received at the control device 130a and/or another control device 130 in the media playback system 100. When arranged in the group 107a, the playback devices 110l and 110m can be configured to play back the same or similar audio content in synchrony from one or more audio content sources. In certain embodiments, for example, the group 107a comprises a bonded zone in which the playback devices 110l and 110m comprise left audio and right audio channels, respectively, of multi-channel audio content, thereby producing or enhancing a stereo effect of the audio content. In some embodiments, the group 107a includes additional playback devices 110. In other embodiments, however, the media playback system 100 omits the group 107a and/or other grouped arrangements of the playback devices 110. Additional details regarding groups and other arrangements of playback devices are described in further detail below with respect to FIGS. 1I-1M.

The media playback system 100 includes the NMDs 120a and 120b, each comprising one or more microphones configured to receive voice utterances from a user. In the illustrated embodiment of FIG. 1B, the NMD 120a is a standalone device and the NMD 120b is integrated into the playback device 110n. The NMD 120a, for example, is configured to receive voice input 121 from a user 123. In some embodiments, the NMD 120a transmits data associated with the received voice input 121 to a voice assistant service (VAS) configured to (i) process the received voice input data and (ii) facilitate one or more operations on behalf of the media playback system 100.

In some aspects, for example, the computing device 106c comprises one or more modules and/or servers of a VAS (e.g., a VAS operated by one or more of SONOS, AMAZON, GOOGLE, APPLE, MICROSOFT, etc.). The computing device 106c can receive the voice input data from the NMD 120a via the network 104 and the links 103.

In response to receiving the voice input data, the computing device 106c processes the voice input data (i.e., “Play Hey Jude by The Beatles”), and determines that the processed voice

input includes a command to play a song (e.g., “Hey Jude”). In some embodiments, after processing the voice input, the computing device 106c accordingly transmits commands to the media playback system 100 to play back “Hey Jude” by the Beatles from a suitable media service (e.g., via one or more of the computing devices 106) on one or more of the playback devices 110. In other embodiments, the computing device 106c may be configured to interface with media services on behalf of the media playback system 100. In such embodiments, after processing the voice input, instead of the computing device 106c transmitting commands to the media playback system 100 causing the media playback system 100 to retrieve the requested media from a suitable media service, the computing device 106c itself causes a suitable media service to provide the requested media to the media playback system 100 in accordance with the user’s voice utterance.

### b. Suitable Playback Devices

FIG. 1C is a block diagram of the playback device 110a comprising an input/output 111. The input/output 111 can include an analog I/O 111a (e.g., one or more wires, cables, and/or other suitable communication links configured to carry analog signals) and/or a digital I/O 111b (e.g., one or more wires, cables, or other suitable communication links configured to carry digital signals). In some embodiments, the analog I/O 111a is an audio line-in input connection comprising, for example, an auto-detecting 3.5mm audio line-in connection. In some embodiments, the digital I/O 111b comprises a Sony/Philips Digital Interface Format (S/PDIF) communication interface and/or cable and/or a Toshiba Link (TOSLINK) cable. In some embodiments, the digital I/O 111b comprises a High-Definition Multimedia Interface (HDMI) interface and/or cable. In some embodiments, the digital I/O 111b includes one or more wireless communication links comprising, for example, a radio frequency (RF), infrared, WI-FI, BLUETOOTH, or another suitable communication link. In certain embodiments, the analog I/O 111a and the digital I/O 111b comprise interfaces (e.g., ports, plugs, jacks, etc.) configured to receive connectors of cables transmitting analog and digital signals, respectively, without necessarily including cables.

The playback device 110a, for example, can receive media content (e.g., audio content comprising music and/or other sounds) from a local audio source 105 via the input/output 111 (e.g., a cable, a wire, a PAN, a BLUETOOTH connection, an ad hoc wired or wireless communication network, and/or another suitable communication link). The local audio source 105 can comprise, for example, a mobile device (e.g., a smartphone, a tablet, a laptop computer, etc.) or another suitable audio component (e.g., a television, a desktop computer, an amplifier, a phonograph (such as an LP turntable), a Blu-ray player, a memory storing digital media files, etc.). In some aspects, the local audio source 105 includes local music libraries on a smartphone, a computer, a networked-attached storage (NAS), and/or another suitable device configured to store media files. In certain embodiments, one or more of the playback devices 110, NMDs 120, and/or control devices 130 comprise the local audio source 105. In other embodiments, however, the media playback system omits the local audio source 105 altogether. In some embodiments, the playback device 110a does not include an input/output 111 and receives all audio content via the network 104.

The playback device 110a further comprises electronics 112, a user interface 113 (e.g., one or more buttons, knobs, dials, touch-sensitive surfaces, displays, touchscreens, etc.), and one or more transducers 114 (referred to hereinafter as “the transducers 114”). The electronics 112 are configured to receive audio from an audio source (e.g., the local audio source 105) via the input/output 111 or one or more of the computing devices 106a-c via the network 104 (FIG. 1B), amplify the received audio, and output the amplified audio for playback via one or more of the transducers 114. In some embodiments, the playback device 110a optionally includes one or more microphones 115 (e.g., a single microphone, a plurality of microphones, a microphone array) (hereinafter referred to as “the microphones 115”). In certain embodiments, for example, the playback device 110a having one or more of the optional microphones 115 can operate as an NMD configured to receive voice input from a user and correspondingly perform one or more operations based on the received voice input.

In the illustrated embodiment of FIG. 1C, the electronics 112 comprise one or more processors 112a (referred to hereinafter as “the processors 112a”), memory 112b, software components 112c, a network interface 112d, one or more audio processing components 112g (referred to hereinafter as “the audio components 112g”), one or more audio amplifiers 112h (referred to hereinafter as “the amplifiers 112h”), and power 112i (e.g., one or more power supplies, power cables, power receptacles, batteries, induction coils, Power-over Ethernet (POE) interfaces, and/or other suitable sources of electric power). In some embodiments, the electronics 112 optionally include one or more other components 112j (e.g., one or more sensors, video displays, touchscreens, battery charging bases, etc.).

The processors 112a can comprise clock-driven computing component(s) configured to process data, and the memory 112b can comprise a computer-readable medium (e.g., a tangible, non-transitory computer-readable medium loaded with one or more of the software components 112c) configured to store instructions for performing various operations and/or functions. The processors 112a are configured to execute the instructions stored on the memory 112b to perform one or more of the operations. The operations can include, for example, causing the playback device 110a to retrieve audio data from an audio source (e.g., one or more of the computing devices 106a-c (FIG. 1B)), and/or another one of the playback devices 110. In some embodiments, the operations further include causing the playback device 110a to send audio data to another one of the playback devices 110a and/or another device (e.g., one of the NMDs 120). Certain embodiments include operations causing the playback device 110a to pair with another of the one or more playback devices 110 to enable a multi-channel audio environment (e.g., a stereo pair, a bonded zone, etc.).

The processors 112a can be further configured to perform operations causing the playback device 110a to synchronize playback of audio content with another of the one or more playback devices 110. As those of ordinary skill in the art will appreciate, during synchronous playback of audio content on a plurality of playback devices, a listener will preferably be unable to perceive time-delay differences between playback of the audio content by the playback device 110a and the other one or more other playback devices 110. Additional details regarding audio playback synchronization among playback devices can be found, for example, in U.S. Patent No. 8,234,395, which was incorporated by reference above.

In some embodiments, the memory 112b is further configured to store data associated with the playback device 110a, such as one or more zones and/or zone groups of which the playback device 110a is a member, audio sources accessible to the playback device 110a, and/or a playback queue that the playback device 110a (and/or another of the one or more playback devices) can be associated with. The stored data can comprise one or more state variables that are periodically updated and used to describe a state of the playback device 110a. The memory 112b can also include data associated with a state of one or more of the other devices (e.g., the playback devices 110, NMDs 120, control devices 130) of the media playback system 100. In some aspects, for example, the state data is shared during predetermined intervals of time (e.g., every 5 seconds, every 10 seconds, every 60 seconds, etc.) among at least a portion of the devices of the media playback system 100, so that one or more of the devices have the most recent data associated with the media playback system 100.

The network interface 112d is configured to facilitate a transmission of data between the playback device 110a and one or more other devices on a data network such as, for example, the links 103 and/or the network 104 (FIG. 1B). The network interface 112d is configured to transmit and receive data corresponding to media content (e.g., audio content, video content, text, photographs) and other signals (e.g., non-transitory signals) comprising digital packet data including an Internet Protocol (IP)-based source address and/or an IP-based destination address. The network interface 112d can parse the digital packet data such that the electronics 112 properly receive and process the data destined for the playback device 110a.

In the illustrated embodiment of FIG. 1C, the network interface 112d comprises one or more wireless interfaces 112e (referred to hereinafter as “the wireless interface 112e”). The wireless interface 112e (e.g., a suitable interface comprising one or more antennae) can be configured to wirelessly communicate with one or more other devices (e.g., one or more of the other playback devices 110, NMDs 120, and/or control devices 130) that are communicatively coupled to the network 104 (FIG. 1B) in accordance with a suitable wireless communication protocol (e.g., WI-FI, BLUETOOTH, LTE, etc.). In some embodiments, the network interface 112d optionally includes a wired interface 112f (e.g., an interface or receptacle configured to receive a network cable such as an Ethernet, a USB-A, USB-C, and/or Thunderbolt cable) configured to communicate over a wired connection with other devices in accordance with a suitable wired communication protocol. In certain embodiments, the network interface 112d includes the wired interface 112f and excludes the wireless interface 112e. In some embodiments, the electronics 112 exclude the network interface 112d altogether and transmit and receive media content and/or other data via another communication path (e.g., the input/output 111).

The audio components 112g are configured to process and/or filter data comprising media content received by the electronics 112 (e.g., via the input/output 111 and/or the network interface 112d) to produce output audio signals. In some embodiments, the audio processing components 112g comprise, for example, one or more digital-to-analog converters (DACs), audio preprocessing components, audio enhancement components, digital signal processors (DSPs), and/or other suitable audio processing components, modules, circuits, etc. In certain embodiments, one or more of the audio processing components 112g can comprise one or more subcomponents of the processors 112a. In some embodiments, the electronics 112 omit the audio processing components 112g. In some aspects, for example, the processors 112a execute instructions stored on the memory 112b to perform audio processing operations to produce the output audio signals.

The amplifiers 112h are configured to receive and amplify the audio output signals produced by the audio processing components 112g and/or the processors 112a. The amplifiers 112h can comprise electronic devices and/or components configured to amplify audio signals to levels sufficient for driving one or more of the transducers 114. In some embodiments, for example, the amplifiers 112h include one or more switching or class-D power amplifiers. In other embodiments, however, the amplifiers 112h include one or more other types of power amplifiers (e.g., linear gain power amplifiers, class-A amplifiers, class-B amplifiers, class-AB amplifiers, class-C amplifiers, class-D amplifiers, class-E amplifiers, class-F amplifiers, class-G amplifiers, class H amplifiers, and/or another suitable type of power amplifier). In certain embodiments, the amplifiers 112h comprise a suitable combination of two or more of the foregoing types of power amplifiers. Moreover, in some embodiments, individual ones of the amplifiers 112h correspond to individual ones of the transducers 114. In other embodiments, however, the electronics 112 include a single one of the amplifiers 112h configured to output amplified audio signals to a plurality of the transducers 114. In some other embodiments, the electronics 112 omit the amplifiers 112h.

The transducers 114 (e.g., one or more speakers and/or speaker drivers) receive the amplified audio signals from the amplifier 112h and render or output the amplified audio signals as sound (e.g., audible sound waves having a frequency between about 20 Hertz (Hz) and 20 kilohertz (kHz)). In some embodiments, the transducers 114 can comprise a single transducer. In other embodiments, however, the transducers 114 comprise a plurality of audio transducers. In some embodiments, the transducers 114 comprise more than one type of transducer. For example, the transducers 114 can include one or more low frequency transducers (e.g., subwoofers, woofers), mid-range frequency transducers (e.g., mid-range transducers, mid-woofers), and one or more high frequency transducers (e.g., one or more tweeters). As used herein, “low frequency” can generally refer to audible frequencies below about 500 Hz, “mid-range frequency” can generally refer to audible frequencies between about 500 Hz and about 2 kHz, and “high frequency” can generally refer to audible frequencies above 2 kHz. In certain embodiments, however, one or more of the transducers 114 comprise transducers that do not adhere to the foregoing frequency ranges. For example, one of the transducers 114 may comprise a mid-woofer transducer configured to output sound at frequencies between about 200 Hz and about 5 kHz.

By way of illustration, Sonos, Inc. presently offers (or has offered) for sale certain playback devices including, for example, a “SONOS ONE,” “PLAY:1,” “PLAY:3,” “PLAY:5,” “PLAYBAR,” “PLAYBASE,” “CONNECT:AMP,” “CONNECT,” “AMP,” “PORT,” and “SUB.” Other suitable playback devices may additionally or alternatively be used to implement the playback devices of example embodiments disclosed herein. Additionally, one of ordinary skill in the art will appreciate that a playback device is not limited to the examples described herein or to Sonos product offerings. In some embodiments, for example, one or more playback devices 110 comprise wired or wireless headphones (e.g., over-the-ear headphones, on-ear headphones, in-ear earphones, etc.). In other embodiments, one or more of the playback devices 110 comprise a docking station and/or an interface configured to interact with a docking station for personal mobile media playback devices. In certain embodiments, a playback device may be integral to another device or component such as a television, an LP turntable, a lighting fixture, or some other device for indoor or outdoor use. In some embodiments, a playback device omits a user interface and/or one or more transducers. For example, FIG. 1D is a block diagram of a playback device 110p comprising the input/output 111 and electronics 112 without the user interface 113 or transducers 114.

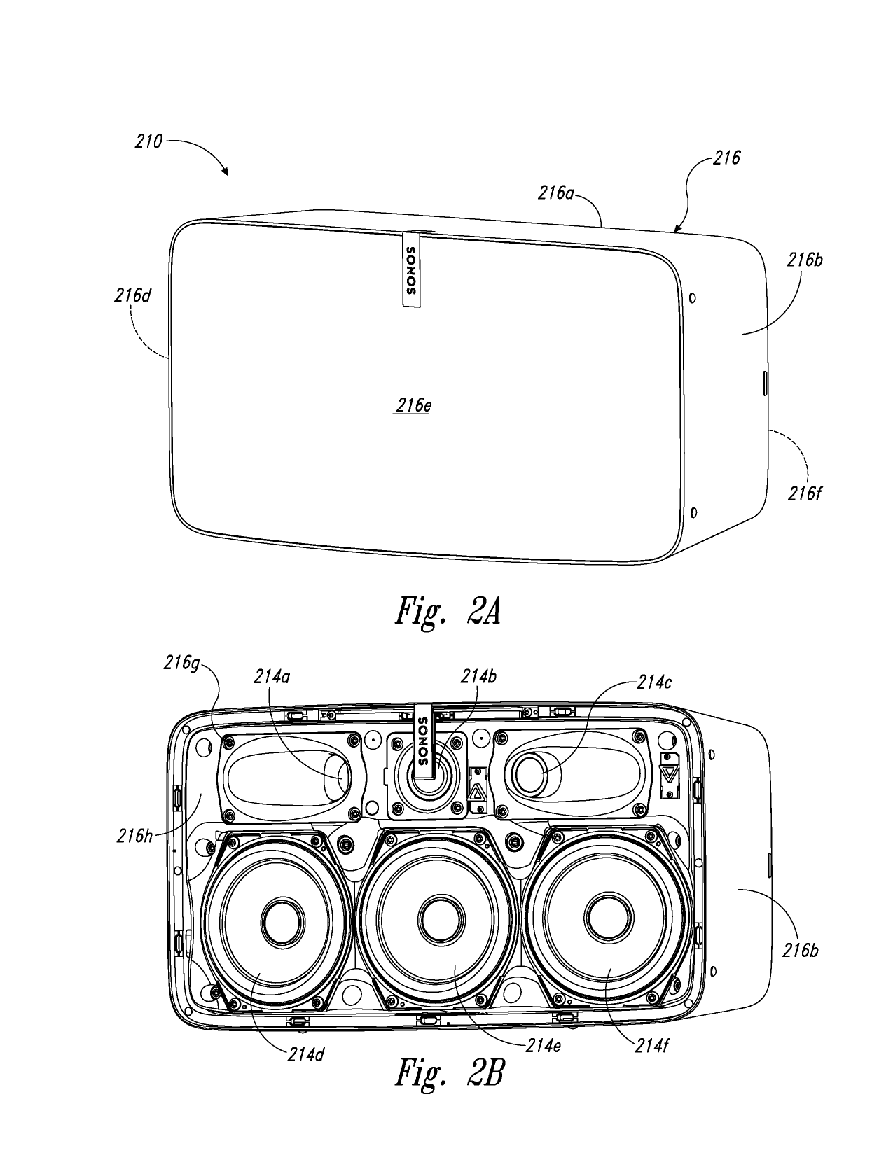

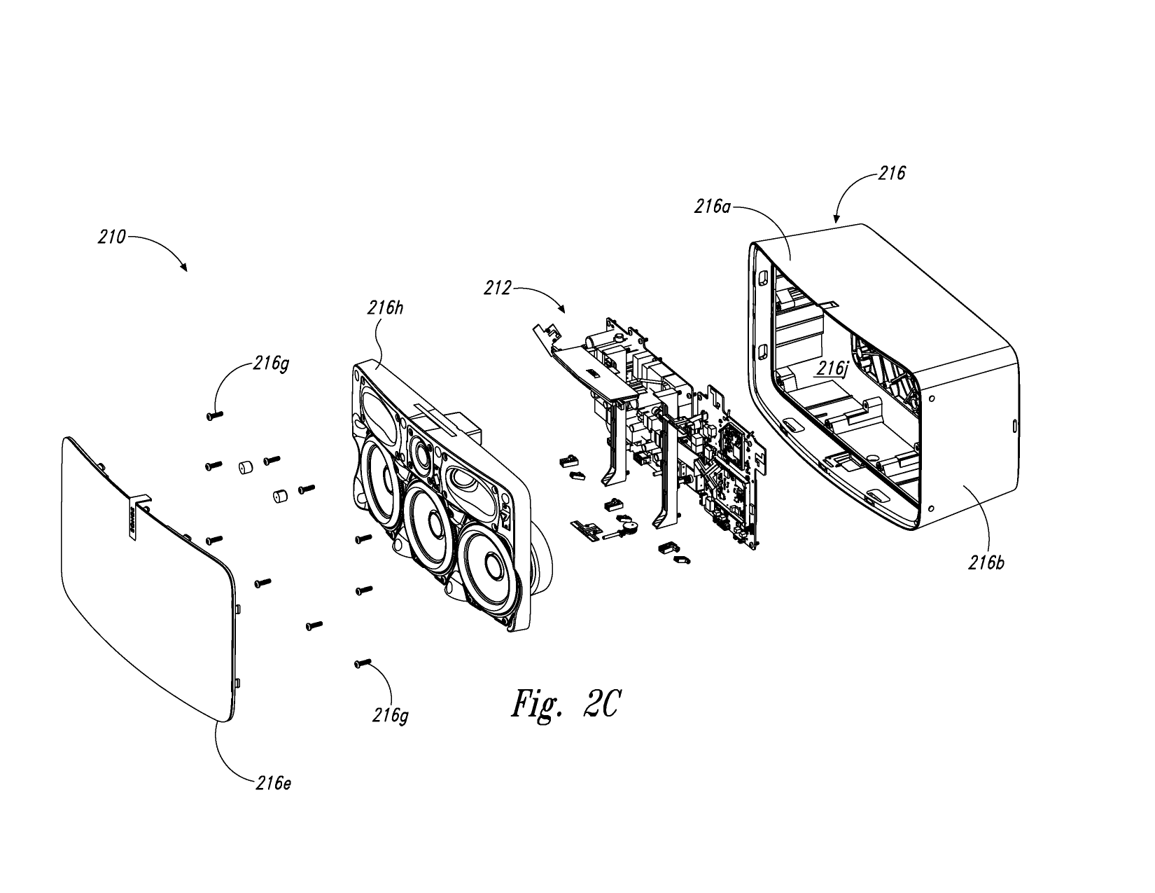

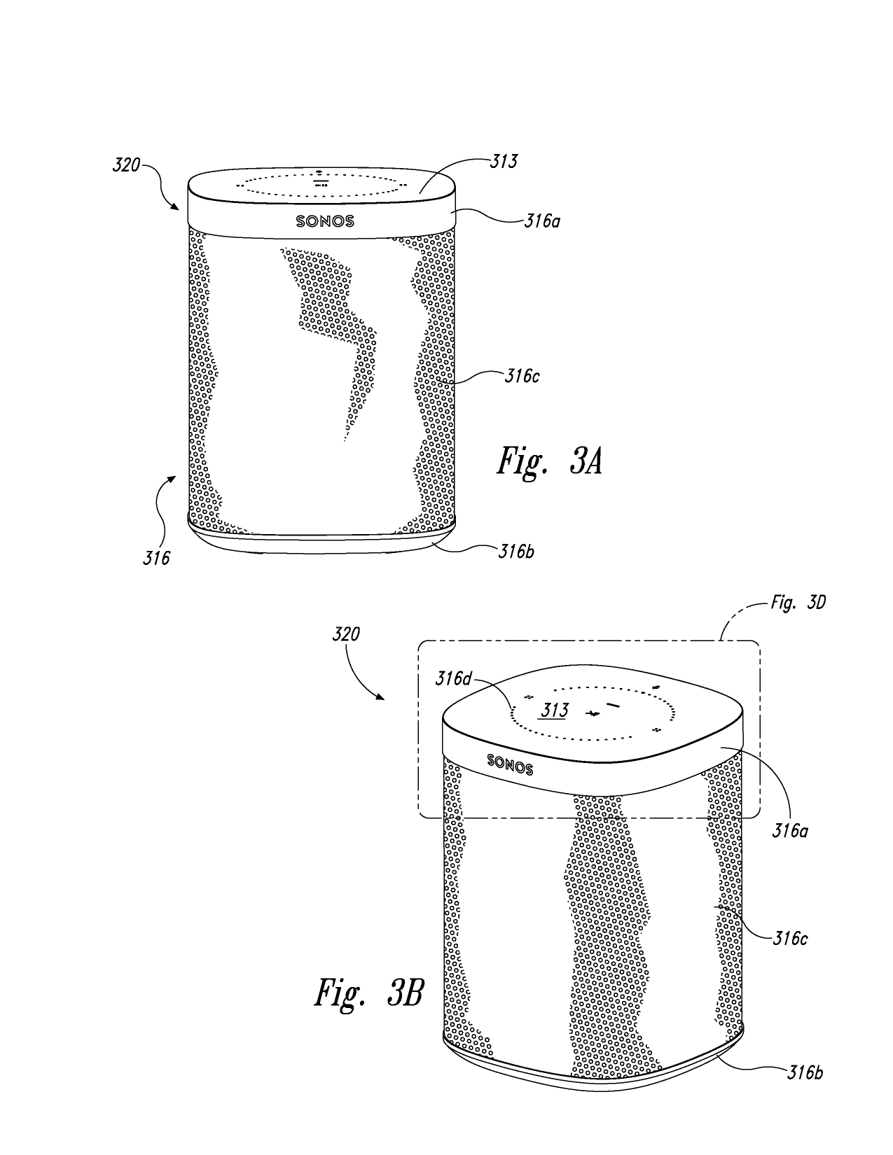

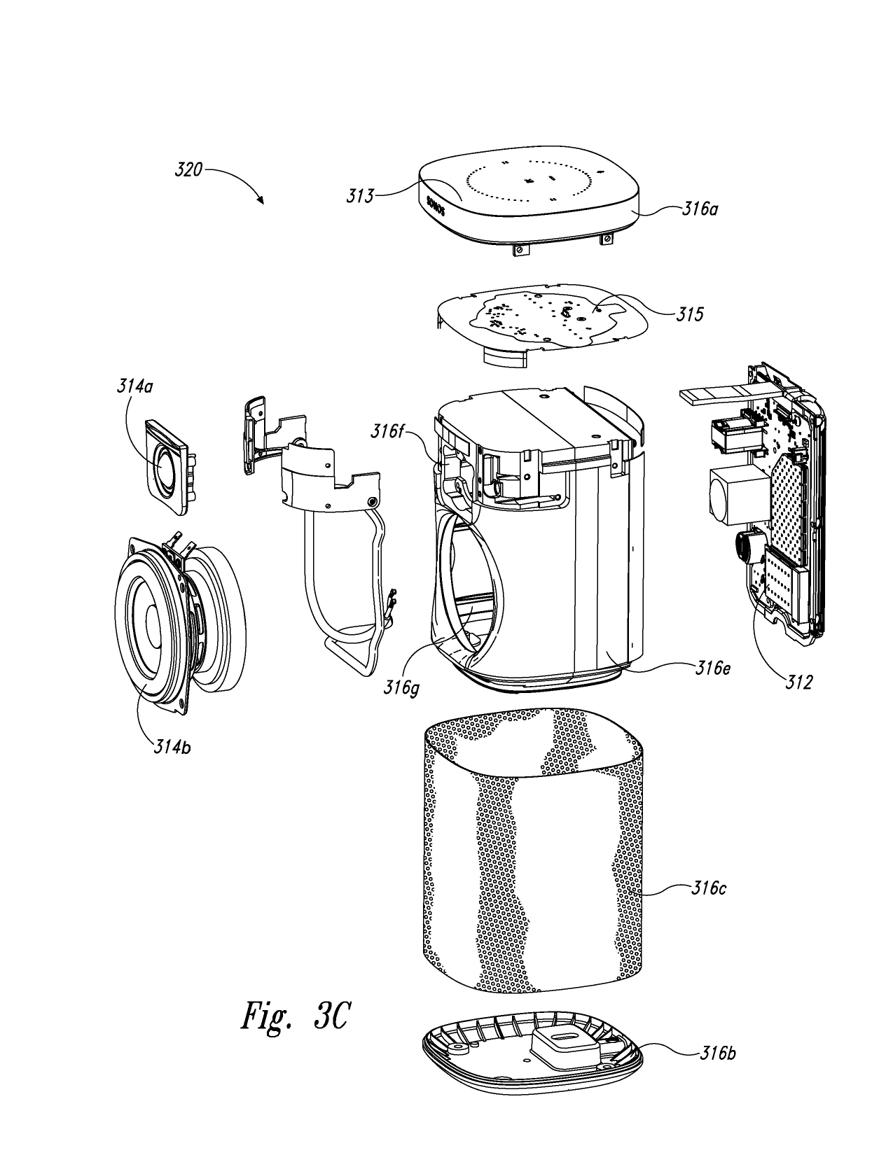

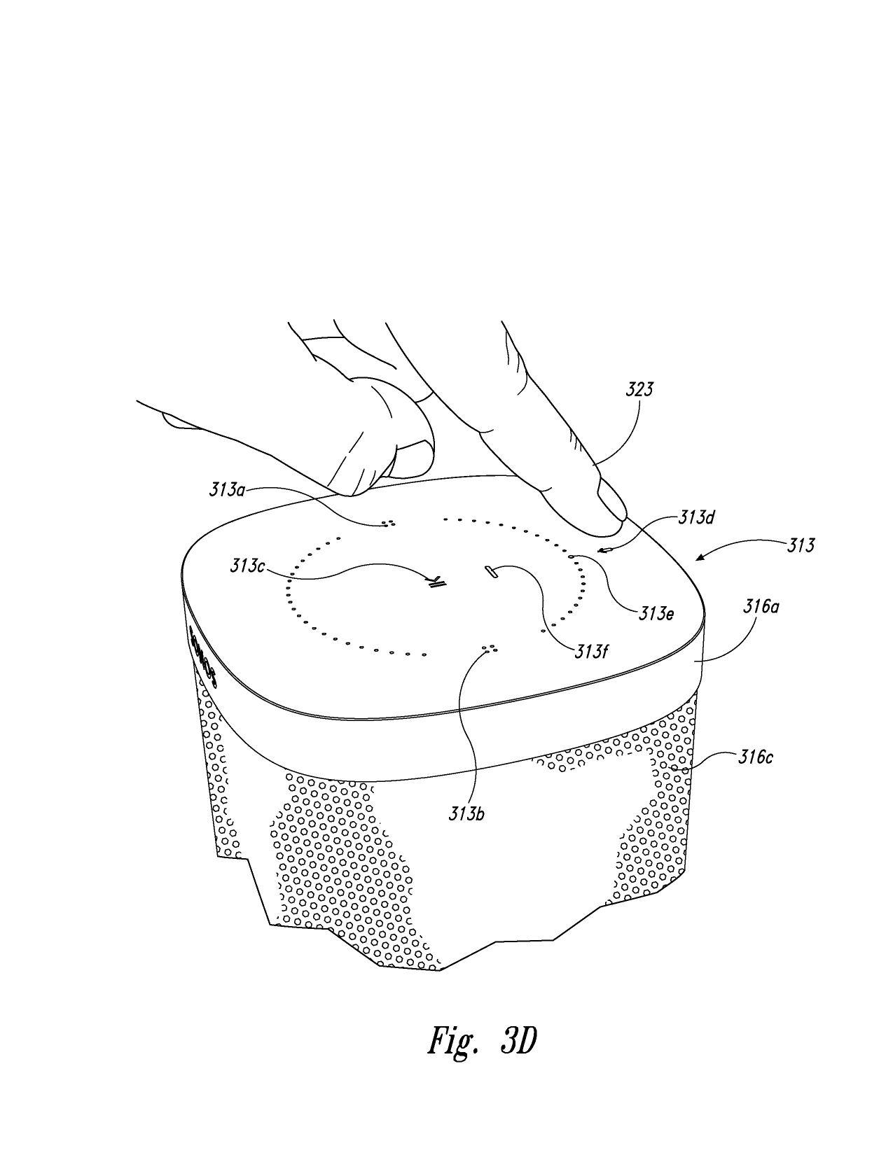

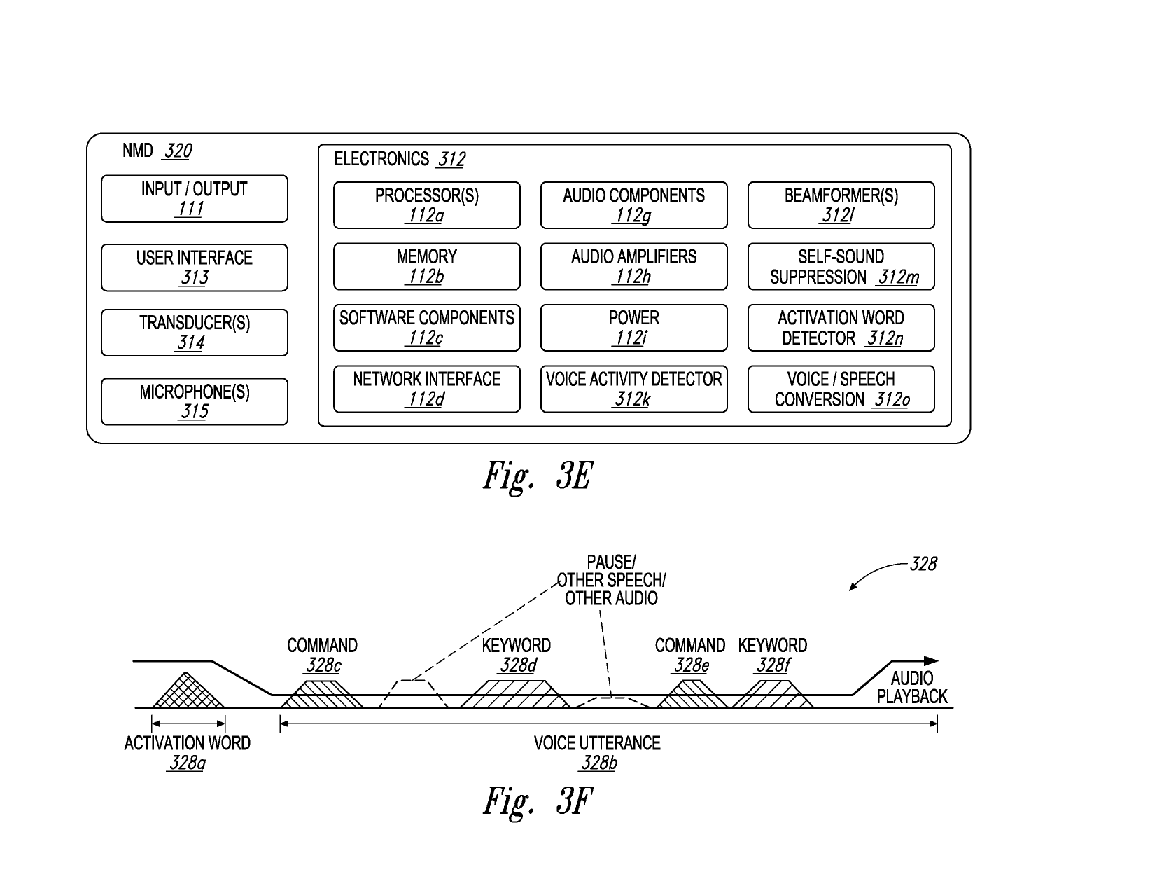

FIG. 1E is a block diagram of a bonded playback device 110q comprising the playback device 110a (FIG. 1C) sonically bonded with the playback device 110i (e.g., a subwoofer) (FIG. 1A). In the illustrated embodiment, the playback devices 110a and 110i are separate ones of the playback devices 110 housed in separate enclosures. In some embodiments, however, the bonded playback device 110q comprises a single enclosure housing both the playback devices 110a and 110i. The bonded playback device 110q can be configured to process and reproduce sound differently than an unbonded playback device (e.g., the playback device 110a of FIG. 1C) and/or paired or bonded playback devices (e.g., the playback devices 110l and 110m of FIG. 1B). In some embodiments, for example, the playback device 110a is a full-range playback device configured to render low frequency, mid-range frequency, and high frequency audio content, and the playback device 110i is a subwoofer configured to render low frequency audio content. In some aspects, the playback device 110a, when bonded with the first playback device, is configured to render only the mid-range and high frequency components of a particular audio content, while the playback device 110i renders the low frequency component of the particular audio content. In some embodiments, the bonded playback device 110q includes additional playback devices and/or another bonded playback device. Additional playback device embodiments are described in further detail below with respect to FIGS. 2A-3D.”

### c. Suitable Network Microphone Devices (NMDs)

FIG. 1F is a block diagram of the NMD 120a (FIGS. 1A and 1B). The NMD 120a includes one or more voice processing components 124 (hereinafter “the voice components 124”) and several components described with respect to the playback device 110a (FIG. 1C) including the processors 112a, the memory 112b, and the microphones 115. The NMD 120a optionally comprises other components also included in the playback device 110a (FIG. 1C), such as the user interface 113 and/or the transducers 114. In some embodiments, the NMD 120a is configured as a media playback device (e.g., one or more of the playback devices 110), and further includes, for example, one or more of the audio components 112g (FIG. 1C), the amplifiers 112h, and/or other playback device components. In certain embodiments, the NMD 120a comprises an Internet of Things (IoT) device such as, for example, a thermostat, alarm panel, fire and/or smoke detector, etc. In some embodiments, the NMD 120a comprises the microphones 115, the voice processing components 124, and only a portion of the components of the electronics 112 described above with respect to FIG. 1C. In some aspects, for example, the NMD 120a includes the processor 112a and the memory 112b (FIG. 1C), while omitting one or more other components of the electronics 112. In some embodiments, the NMD 120a includes additional components (e.g., one or more sensors, cameras, thermometers, barometers, hygrometers, etc.).

In some embodiments, an NMD can be integrated into a playback device. FIG. 1G is a block diagram of a playback device 110r comprising an NMD 120d. The playback device 110r can comprise many or all of the components of the playback device 110a and further include the microphones 115 and voice processing components 124 (FIG. 1F). The playback device 110r optionally includes an integrated control device 130c. The control device 130c can comprise, for example, a user interface (e.g., the user interface 113 of FIG. 1C) configured to receive user input (e.g., touch input, voice input, etc.) without a separate control device. In other embodiments, however, the playback device 110r receives commands from another control device (e.g., the control device 130a of FIG. 1B). Additional NMD embodiments are described in further detail below with respect to FIGS. 3A-3F.

Referring again to FIG. 1F, the microphones 115 are configured to acquire, capture, and/or receive sound from an environment (e.g., the environment 101 of FIG. 1A) and/or a room in which the NMD 120a is positioned. The received sound can include, for example, vocal utterances, audio played back by the NMD 120a and/or another playback device, background voices, ambient sounds, etc. The microphones 115 convert the received sound into electrical signals to produce microphone data. The voice processing components 124 receive and analyze the microphone data to determine whether a voice input is present in the microphone data. The voice input can comprise, for example, an activation word followed by an utterance including a user request. As those of ordinary skill in the art will appreciate, an activation word is a word or other audio cue signifying a user voice input. For instance, in querying the AMAZON VAS, a user might speak the activation word "Alexa." Other examples include "Ok, Google" for invoking the GOOGLE VAS and "Hey, Siri" for invoking the APPLE VAS.

After detecting the activation word, voice processing components 124 monitor the microphone data for an accompanying user request in the voice input. The user request may include, for example, a command to control a third-party device, such as a thermostat (e.g., NEST thermostat), an illumination device (e.g., a PHILIPS HUE lighting device), or a media playback device (e.g., a SONOS playback device). For example, a user might speak the activation word “Alexa” followed by the utterance “set the thermostat to 68 degrees” to set a temperature in a home (e.g., the environment 101 of FIG. 1A). The user might speak the same activation word followed by the utterance “turn on the living room” to turn on illumination devices in a living room area of the home. The user may similarly speak an activation word followed by a request to play a particular song, an album, or a playlist of music on a playback device in the home. Additional description regarding receiving and processing voice input data can be found in further detail below with respect to FIGS. 3A-3F.

### d. Suitable Control Devices

FIG. 1H is a partial schematic diagram of the control device 130a (FIGS. 1A and 1B). As used herein, the term “control device” can be used interchangeably with “controller” or “control system.” Among other features, the control device 130a is configured to receive user input related to the media playback system 100 and, in response, cause one or more devices in the media playback system 100 to perform an action(s) or operation(s) corresponding to the user input. In the illustrated embodiment, the control device 130a comprises a smartphone (e.g., an iPhone^{™}_{,} an Android phone, etc.) on which media playback system controller application software is installed.

In some embodiments, the control device 130a comprises, for example, a tablet (e.g., an iPad™), a computer (e.g., a laptop computer, a desktop computer, etc.), and/or another suitable device (e.g., a television, an automobile audio head unit, an IoT device, etc.). In certain embodiments, the control device 130a comprises a dedicated controller for the media playback system 100. In other embodiments, as described above with respect to FIG. 1G, the control device 130a is integrated into another device in the media playback system 100 (e.g., one more of the playback devices 110, NMDs 120, and/or other suitable devices configured to communicate over a network).

The control device 130a includes electronics 132, a user interface 133, one or more speakers 134, and one or more microphones 135. The electronics 132 comprise one or more processors 132a (referred to hereinafter as “the processors 132a”), a memory 132b, software components 132c, and a network interface 132d. The processor 132a can be configured to perform functions relevant to facilitating user access, control, and configuration of the media playback system 100. The memory 132b can comprise data storage that can be loaded with one or more of the software components executable by the processor 132a to perform those functions. The software components 132c can comprise applications and/or other executable software configured to facilitate control of the media playback system 100. The memory 132b can be configured to store, for example, the software components 132c, media playback system controller application software, and/or other data associated with the media playback system 100 and the user.

The network interface 132d is configured to facilitate network communications between the control device 130a and one or more other devices in the media playback system 100, and/or one or more remote devices. In some embodiments, the network interface 132d is configured to operate according to one or more suitable communication industry standards (e.g., infrared, radio, wired standards including IEEE 802.3, wireless standards including IEEE 802.11a, 802.11b, 802.11g, 802.11n, 802.11ac, 802.15, 4G, LTE, etc.). The network interface 132d can be configured, for example, to transmit data to and/or receive data from the playback devices 110, the NMDs 120, other ones of the control devices 130, one of the computing devices 106 of FIG. 1B, devices comprising one or more other media playback systems, etc. The transmitted and/or received data can include, for example, playback device control commands, state variables,

playback zone and/or zone group configurations. For instance, based on user input received at the user interface 133, the network interface 132d can transmit a playback device control command (e.g., volume control, audio playback control, audio content selection, etc.) from the control device 130a to one or more of the playback devices 110. The network interface 132d can also transmit and/or receive configuration changes such as, for example, adding/removing one or more playback devices 110 to/from a zone, adding/removing one or more zones to/from a zone group, forming a bonded or consolidated player, separating one or more playback devices from a bonded or consolidated player, among others. Additional description of zones and groups can be found below with respect to FIGS. 1I through 1M.

The user interface 133 is configured to receive user input and can facilitate control of the media playback system 100. The user interface 133 includes media content art 133a (e.g., album art, lyrics, videos, etc.), a playback status indicator 133b (e.g., an elapsed and/or remaining time indicator), media content information region 133c, a playback control region 133d, and a zone indicator 133e. The media content information region 133c can include a display of relevant information (e.g., title, artist, album, genre, release year, etc.) about media content currently playing and/or media content in a queue or playlist. The playback control region 133d can include selectable (e.g., via touch input and/or via a cursor or another suitable selector) icons to cause one or more playback devices in a selected playback zone or zone group to perform playback actions such as, for example, play or pause, fast forward, rewind, skip to next, skip to previous, enter/exit shuffle mode, enter/exit repeat mode, enter/exit cross fade mode, etc. The playback control region 133d may also include selectable icons to modify equalization settings, playback volume, and/or other suitable playback actions. In the illustrated embodiment, the user interface 133 comprises a display presented on a touch screen interface of a smartphone (e.g., an iPhone^{™}_{,} an Android phone, etc.). In some embodiments, however, user interfaces of varying formats, styles, and interactive sequences may alternatively be implemented on one or more network devices to provide comparable control access to a media playback system.

The one or more speakers 134 (e.g., one or more transducers) can be configured to output sound to the user of the control device 130a. In some embodiments, the one or more speakers

comprise individual transducers configured to correspondingly output low frequencies, mid-range frequencies, and/or high frequencies. In some aspects, for example, the control device 130a is configured as a playback device (e.g., one of the playback devices 110). Similarly, in some embodiments the control device 130a is configured as an NMD (e.g., one of the NMDs 120), receiving voice commands and other sounds via the one or more microphones 135.

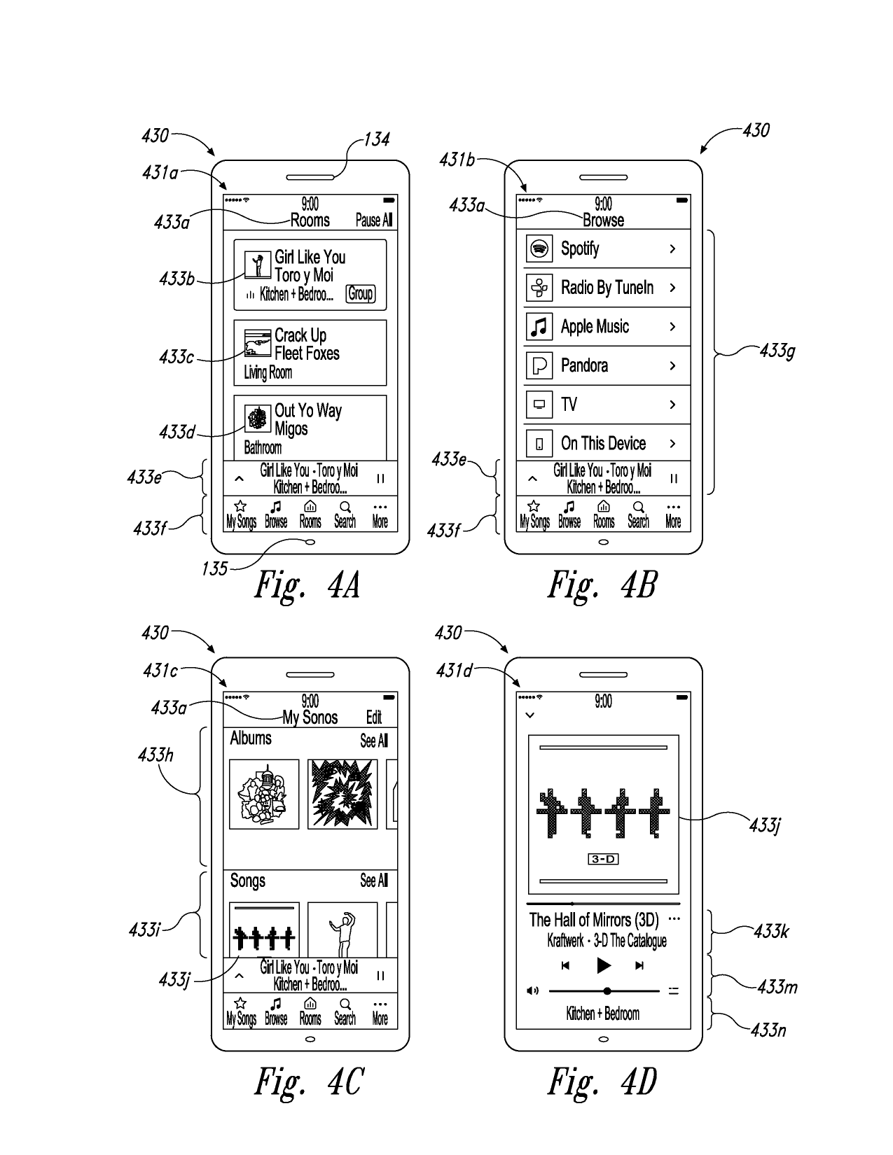

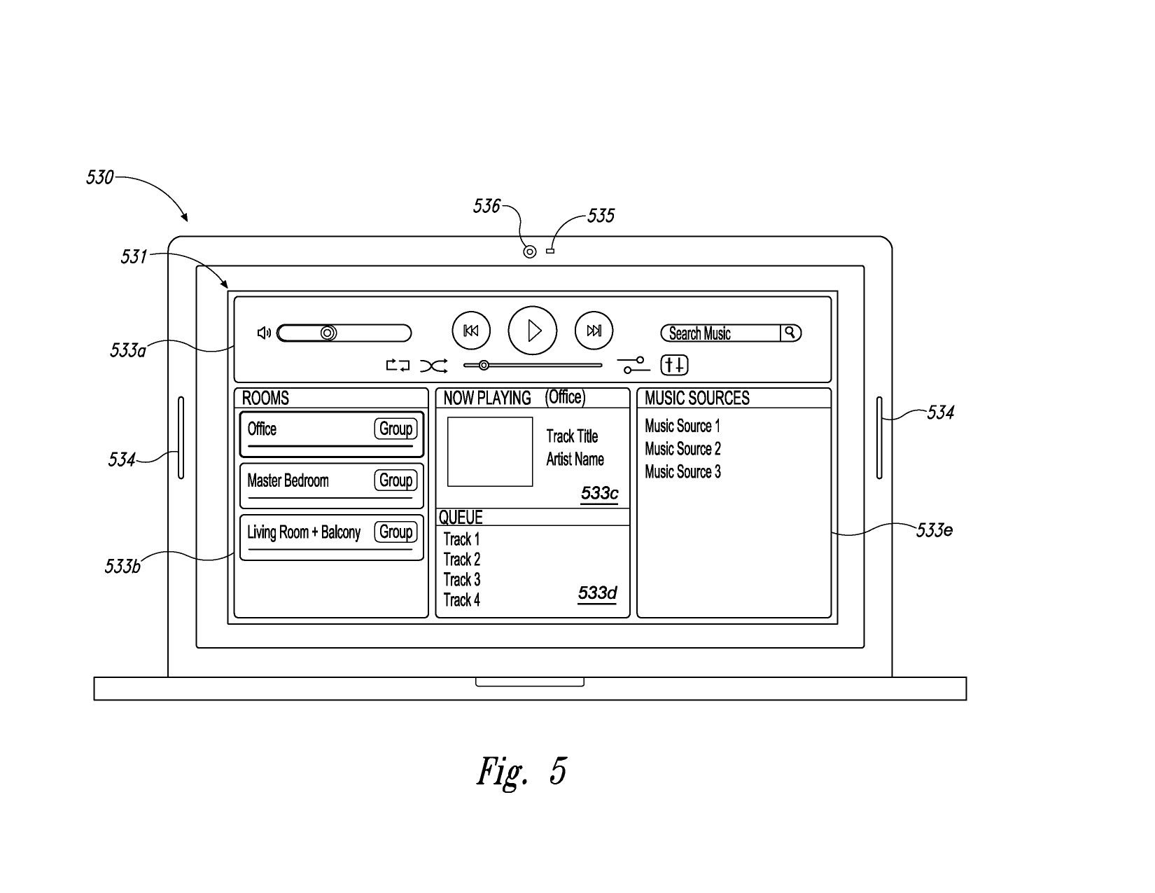

The one or more microphones 135 can comprise, for example, one or more condenser microphones, electret condenser microphones, dynamic microphones, and/or other suitable types of microphones or transducers. In some embodiments, two or more of the microphones 135 are arranged to capture location information of an audio source (e.g., voice, audible sound, etc.) and/or configured to facilitate filtering of background noise. Moreover, in certain embodiments, the control device 130a is configured to operate as a playback device and an NMD. In other embodiments, however, the control device 130a omits the one or more speakers 134 and/or the one or more microphones 135. For instance, the control device 130a may comprise a device (e.g., a thermostat, an IoT device, a network device, etc.) comprising a portion of the electronics 132 and the user interface 133 (e.g., a touch screen) without any speakers or microphones. Additional control device embodiments are described in further detail below with respect to FIGS. 4A-4D and 5.

### e. Suitable Playback Device Configurations

FIGS. 1I through 1M show example configurations of playback devices in zones and zone groups. Referring first to FIG. 1M, in one example, a single playback device may belong to a zone. For example, the playback device 110g in the second bedroom 101c (FIG. 1A) may belong to Zone C. In some implementations described below, multiple playback devices may be “bonded” to form a “bonded pair” which together form a single zone. For example, the playback device 110l (e.g., a left playback device) can be bonded to the playback device 110m (e.g., a right playback device) to form Zone B. Bonded playback devices may have different playback responsibilities (e.g., channel responsibilities). In another implementation described below, multiple playback devices may be merged to form a single zone. For example, the playback device 110h (e.g., a front

playback device) may be merged with the playback device 110i (e.g., a subwoofer), and the playback devices 110j and 110k (e.g., left and right surround speakers, respectively) to form a single Zone D. In another example, the playback devices 110b and 110d can be merged to form a merged group or a zone group 108b. The merged playback devices 110b and 110d may not be specifically assigned different playback responsibilities. That is, the merged playback devices 110b and 110d may, aside from playing audio content in synchrony, each play audio content as they would if they were not merged.

Each zone in the media playback system 100 may be provided for control as a single user interface (UI) entity. For example, Zone A may be provided as a single entity named Master Bathroom. Zone B may be provided as a single entity named Master Bedroom. Zone C may be provided as a single entity named Second Bedroom.

Playback devices that are bonded may have different playback responsibilities, such as responsibilities for certain audio channels. For example, as shown in FIG. 1I, the playback devices 110l and 110m may be bonded so as to produce or enhance a stereo effect of audio content. In this example, the playback device 110l may be configured to play a left channel audio component, while the playback device 110m may be configured to play a right channel audio component. In some implementations, such stereo bonding may be referred to as “pairing.”

Additionally, bonded playback devices may have additional and/or different respective speaker drivers. As shown in FIG. 1J, the playback device 110h named Front may be bonded with the playback device 110i named SUB. The Front device 110h can be configured to render a range of mid to high frequencies and the SUB device 110i can be configured to render low frequencies. When unbonded, however, the Front device 110h can be configured to render a full range of frequencies. As another example, FIG. 1K shows the Front and SUB devices 110h and 110i further bonded with Left and Right playback devices 110j and 110k, respectively. In some implementations, the Left and Right devices 110j and 110k can be configured to form surround or “satellite” channels of a home theater system. The bonded playback devices 110h, 110i, 110j, and 110k may form a single Zone D (FIG. 1M).

Playback devices that are merged may not have assigned playback responsibilities, and may each render the full range of audio content the respective playback device is capable of. Nevertheless, merged devices may be represented as a single UI entity (i.e., a zone, as discussed above). For instance, the playback devices 110a and 110n in the master bathroom have the single UI entity of Zone A. In one embodiment, the playback devices 110a and 110n may each output the full range of audio content each respective playback devices 110a and 110n are capable of, in synchrony.

In some embodiments, an NMD is bonded or merged with another device so as to form a zone. For example, the NMD 120b may be bonded with the playback device 110e, which together form Zone F, named Living Room. In other embodiments, a stand-alone network microphone device may be in a zone by itself. In other embodiments, however, a stand-alone network microphone device may not be associated with a zone. Additional details regarding associating network microphone devices and playback devices as designated or default devices may be found, for example, in subsequently referenced U.S. Patent No. 10,499,146.

Zones of individual, bonded, and/or merged devices may be grouped to form a zone group. For example, referring to FIG. 1M, Zone A may be grouped with Zone B to form a zone group 108a that includes the two zones. Similarly, Zone G may be grouped with Zone H to form the zone group 108b. As another example, Zone A may be grouped with one or more other Zones C-I. The Zones A-I may be grouped and ungrouped in numerous ways. For example, three, four, five, or more (e.g., all) of the Zones A-I may be grouped. When grouped, the zones of individual and/or bonded playback devices may play back audio in synchrony with one another, as described in previously referenced U.S. Patent No. 8,234,395. Playback devices may be dynamically grouped and ungrouped to form new or different groups that synchronously play back audio content.

In various implementations, the zones in an environment may be the default name of a zone within the group or a combination of the names of the zones within a zone group. For example,

Zone Group 108b can be assigned a name such as “Dining + Kitchen”, as shown in FIG. 1M. In some embodiments, a zone group may be given a unique name selected by a user.

Certain data may be stored in a memory of a playback device (e.g., the memory 112b of FIG. 1C) as one or more state variables that are periodically updated and used to describe the state of a playback zone, the playback device(s), and/or a zone group associated therewith. The memory may also include the data associated with the state of the other devices of the media system, and shared from time to time among the devices so that one or more of the devices have the most recent data associated with the system.

In some embodiments, the memory may store instances of various variable types associated with the states. Variable instances may be stored with identifiers (e.g., tags) corresponding to type. For example, certain identifiers may be a first type “a1” to identify playback device(s) of a zone, a second type “b1” to identify playback device(s) that may be bonded in the zone, and a third type “c1” to identify a zone group to which the zone may belong. As a related example, identifiers associated with the second bedroom 101c may indicate that the playback device is the only playback device of the Zone C and not in a zone group. Identifiers associated with the Den may indicate that the Den is not grouped with other zones but includes bonded playback devices 110h-110k. Identifiers associated with the Dining Room may indicate that the Dining Room is part of the Dining + Kitchen zone group 108b and that devices 110b and 110d are grouped (FIG. 1L). Identifiers associated with the Kitchen may indicate the same or similar information by virtue of the Kitchen being part of the Dining + Kitchen zone group 108b. Other example zone variables and identifiers are described below.

In yet another example, the memory may store variables or identifiers representing other associations of zones and zone groups, such as identifiers associated with Areas, as shown in FIG. 1M. An area may involve a cluster of zone groups and/or zones not within a zone group. For instance, FIG. 1M shows an Upper Area 109a including Zones A-D and I, and a Lower Area 109b including Zones E-I. In one aspect, an Area may be used to invoke a cluster of zone groups and/or zones that share one or more zones and/or zone groups of another cluster. In another aspect,

this differs from a zone group, which does not share a zone with another zone group. Further examples of techniques for implementing Areas may be found, for example, in U.S. Patent No. 10,712,997 filed August 21, 2017, and titled “Room Association Based on Name,” and U.S. Patent No. 8,483,853 filed September 11, 2007, and titled “Controlling and manipulating groupings in a multi-zone media system.” Each of these patents is incorporated herein by reference in its entirety. In some embodiments, the media playback system 100 may not implement Areas, in which case the system may not store variables associated with Areas.

### III. Example Systems and Devices

FIG. 2A is a front isometric view of a playback device 210 configured in accordance with aspects of the disclosed technology. FIG. 2B is a front isometric view of the playback device 210 without a grille 216e. FIG. 2C is an exploded view of the playback device 210. Referring to FIGS. 2A-2C together, the playback device 210 comprises a housing 216 that includes an upper portion 216a, a right or first side portion 216b, a lower portion, a left or second side portion 216d, the grille 216e, and a rear portion 216f. A plurality of fasteners 216g (e.g., one or more screws, rivets, clips) attaches a frame 216h to the housing 216. A cavity 216j (FIG. 2C) in the housing 216 is configured to receive the frame 216h and electronics 212. The frame 216h is configured to carry a plurality of transducers 214 (identified individually in FIG. 2B as transducers 214a-f). The electronics 212 (e.g., the electronics 112 of FIG. 1C) are configured to receive audio content from an audio source and send electrical signals corresponding to the audio content to the transducers 214 for playback.

The transducers 214 are configured to receive the electrical signals from the electronics 112, and further configured to convert the received electrical signals into audible sound during playback. For instance, the transducers 214a-c (e.g., tweeters) can be configured to output high frequency sound (e.g., sound waves having a frequency greater than about 2 kHz). The transducers 214d-f (e.g., mid-woofers, woofers, midrange speakers) can be configured output sound at frequencies lower than the transducers 214a-c (e.g., sound waves having a frequency lower than about 2 kHz). In some embodiments, the playback device 210 includes a number of transducers

different than those illustrated in FIGS. 2A-2C. For example, as described in further detail below with respect to FIGS. 3A-3C, the playback device 210 can include fewer than six transducers (e.g., one, two, three). In other embodiments, however, the playback device 210 includes more than six transducers (e.g., nine, ten). Moreover, in some embodiments, all or a portion of the transducers 214 are configured to operate as a phased array to desirably adjust (e.g., narrow or widen) a radiation pattern of the transducers 214, thereby altering a user’s perception of the sound emitted from the playback device 210.

In some examples, a filter is axially aligned with the transducer 214b. The filter can be configured to desirably attenuate a predetermined range of frequencies that the transducer 214b outputs to improve sound quality and a perceived sound stage output collectively by the transducers 214. In some embodiments, however, the playback device 210 omits the filter. In other embodiments, the playback device 210 includes one or more additional filters aligned with the transducers 214b and/or at least another of the transducers 214.

FIGS. 3A and 3B are front and right isometric side views, respectively, of an NMD 320 configured in accordance with embodiments of the disclosed technology. FIG. 3C is an exploded view of the NMD 320. FIG. 3D is an enlarged view of a portion of FIG. 3B including a user interface 313 of the NMD 320. Referring first to FIGS. 3A-3C, the NMD 320 includes a housing 316 comprising an upper portion 316a, a lower portion 316b and an intermediate portion 316c (e.g., a grille). A plurality of ports, holes or apertures 316d in the upper portion 316a allow sound to pass through to one or more microphones 315 (FIG. 3C) positioned within the housing 316. The one or more microphones 315 are configured to receive sound via the apertures 316d and produce electrical signals based on the received sound. In the illustrated embodiment, a frame 316e (FIG. 3C) of the housing 316 surrounds cavities 316f and 316g configured to house, respectively, a first transducer 314a (e.g., a tweeter) and a second transducer 314b (e.g., a mid-woofer, a midrange speaker, a woofer). In other embodiments, however, the NMD 320 includes a single transducer, or more than two (e.g., two, five, six) transducers. In certain embodiments, the NMD 320 omits the transducers 314a and 314b altogether.

Electronics 312 (FIG. 3C) includes components configured to drive the transducers 314a and 314b, and further configured to analyze audio data corresponding to the electrical signals produced by the one or more microphones 315. In some embodiments, for example, the electronics 312 comprises many or all of the components of the electronics 112 described above with respect to FIG. 1C. In certain embodiments, the electronics 312 includes components described above with respect to FIG. 1F such as, for example, the one or more processors 112a, the memory 112b, the software components 112c, the network interface 112d, etc. In some embodiments, the electronics 312 includes additional suitable components (e.g., proximity or other sensors).

Referring to FIG. 3D, the user interface 313 includes a plurality of control surfaces (e.g., buttons, knobs, capacitive surfaces) including a first control surface 313a (e.g., a previous control), a second control surface 313b (e.g., a next control), and a third control surface 313c (e.g., a play and/or pause control) that can be adjusted by a user 323. A fourth control surface 313d is configured to receive touch input corresponding to activation and deactivation of the one or microphones 315. A first indicator 313e (e.g., one or more light emitting diodes (LEDs) or another suitable illuminator) can be configured to illuminate only when the one or more microphones 315 are activated. A second indicator 313f (e.g., one or more LEDs) can be configured to remain solid during normal operation and to blink or otherwise change from solid to indicate a detection of voice activity. In some embodiments, the user interface 313 includes additional or fewer control surfaces and illuminators. In one embodiment, for example, the user interface 313 includes the first indicator 313e, omitting the second indicator 313f. Moreover, in certain embodiments, the NMD 320 comprises a playback device and a control device, and the user interface 313 comprises the user interface of the control device.

Referring to FIGS. 3A-3D together, the NMD 320 is configured to receive voice commands from one or more adjacent users via the one or more microphones 315. As described above with respect to FIG. 1B, the one or more microphones 315 can acquire, capture, or record sound in a vicinity (e.g., a region within 10m or less of the NMD 320) and transmit electrical signals corresponding to the recorded sound to the electronics 312. The electronics 312 can process the electrical signals and can analyze the resulting audio data to determine a presence of one or more voice commands (e.g., one or more activation words). In some embodiments, for example, after detection of one or more suitable voice commands, the NMD 320 is configured to transmit a portion of the recorded audio data to another device and/or a remote server (e.g., one or more of the computing devices 106 of FIG. 1B) for further analysis. The remote server can analyze the audio data, determine an appropriate action based on the voice command, and transmit a message to the NMD 320 to perform the appropriate action. For instance, a user may speak “Sonos, play Michael Jackson.” The NMD 320 can, via the one or more microphones 315, record the user’s voice utterance, determine the presence of a voice command, and transmit the audio data having the voice command to a remote server (e.g., one or more of the remote computing devices 106 of FIG. 1B, one or more servers of a VAS and/or another suitable service). The remote server can analyze the audio data and determine an action corresponding to the command. The remote server can then transmit a command to the NMD 320 to perform the determined action (e.g., play back audio content related to Michael Jackson). The NMD 320 can receive the command and play back the audio content related to Michael Jackson from a media content source. As described above with respect to FIG. 1B, suitable content sources can include a device or storage communicatively coupled to the NMD 320 via a LAN (e.g., the network 104 of FIG. 1B), a remote server (e.g., one or more of the remote computing devices 106 of FIG. 1B), etc. In certain embodiments, however, the NMD 320 determines and/or performs one or more actions corresponding to the one or more voice commands without intervention or involvement of an external device, computer, or server.

FIG. 3E is a functional block diagram showing additional features of the NMD 320 in accordance with aspects of the disclosure. The NMD 320 includes components configured to facilitate voice command capture including voice activity detector component(s) 312k, beam former components 312l, acoustic echo cancellation (AEC) and/or self-sound suppression components 312m, activation word detector components 312n, and voice/speech conversion components 312o (e.g., voice-to-text and text-to-voice). In the illustrated embodiment of FIG. 3E, the foregoing components 312k-312o are shown as separate components. In some embodiments, however, one or more of the components 312k-312o are subcomponents of the processors 112a.

The beamforming and self-sound suppression components 312l and 312m are configured to detect an audio signal and determine aspects of voice input represented in the detected audio signal, such as the direction, amplitude, frequency spectrum, etc. The voice activity detector activity components 312k are operably coupled with the beamforming and AEC components 312l and 312m and are configured to determine a direction and/or directions from which voice activity is likely to have occurred in the detected audio signal. Potential speech directions can be identified by monitoring metrics which distinguish speech from other sounds. Such metrics can include, for example, energy within the speech band relative to background noise and entropy within the speech band, which is a measure of spectral structure. As those of ordinary skill in the art will appreciate, speech typically has a lower entropy than most common background noise. The activation word detector components 312n are configured to monitor and analyze received audio to determine if any activation words (e.g., wake words) are present in the received audio. The activation word detector components 312n may analyze the received audio using an activation word detection algorithm. If the activation word detector 312n detects an activation word, the NMD 320 may process voice input contained in the received audio. Example activation word detection algorithms accept audio as input and provide an indication of whether an activation word is present in the audio. Many first- and third-party activation word detection algorithms are known and commercially available. For instance, operators of a voice service may make their algorithm available for use in third-party devices. Alternatively, an algorithm may be trained to detect certain activation words. In some embodiments, the activation word detector 312n runs multiple activation word detection algorithms on the received audio simultaneously (or substantially simultaneously). As noted above, different voice services (e.g., AMAZON’s ALEXA, APPLE’s SIRI, or MICROSOFT’s CORTANA) can each use a different activation word for invoking their respective voice service. To support multiple services, the activation word detector 312n may run the received audio through the activation word detection algorithm for each supported voice service in parallel.

The speech/text conversion components 312o may facilitate processing by converting speech in the voice input to text. In some embodiments, the electronics 312 can include voice recognition software that is trained to a particular user or a particular set of users associated with a household. Such voice recognition software may implement voice-processing algorithms that are tuned to specific voice profile(s). Tuning to specific voice profiles may require less computationally intensive algorithms than traditional voice activity services, which typically sample from a broad base of users and diverse requests that are not targeted to media playback systems.

FIG. 3F is a schematic diagram of an example voice input 328 captured by the NMD 320 in accordance with aspects of the disclosure. The voice input 328 can include an activation word portion 328a and a voice utterance portion 328b. In some embodiments, the activation word 328a can be a known activation word, such as “Alexa,” which is associated with AMAZON’s ALEXA. In other embodiments, however, the voice input 328 may not include an activation word. In some embodiments, a network microphone device may output an audible and/or visible response upon detection of the activation word portion 328a. In addition, or alternately, an NMD may output an audible and/or visible response after processing a voice input and/or a series of voice inputs.

The voice utterance portion 328b may include, for example, one or more spoken commands (identified individually as a first command 328c and a second command 328e) and one or more spoken keywords (identified individually as a first keyword 328d and a second keyword 328f). In one example, the first command 328c can be a command to play music, such as a specific song, album, playlist, etc. In this example, the keywords may be one or words identifying one or more zones in which the music is to be played, such as the Living Room and the Dining Room shown in FIG. 1A. In some examples, the voice utterance portion 328b can include other information, such as detected pauses (e.g., periods of non-speech) between words spoken by a user, as shown in FIG. 3F. The pauses may demarcate the locations of separate commands, keywords, or other information spoken by the user within the voice utterance portion 328b.

In some embodiments, the media playback system 100 is configured to temporarily reduce the volume of audio content that it is playing while detecting the activation word portion 328a. The media playback system 100 may restore the volume after processing the voice input 328, as shown in FIG. 3F. Such a process can be referred to as ducking, examples of which are disclosed in U.S. Patent No. 10,499,146, which is incorporated by reference herein in its entirety.

FIGS. 4A-4D are schematic diagrams of a control device 430 (e.g., the control device 130a of FIG. 1H, a smartphone, a tablet, a dedicated control device, an IoT device, and/or another suitable device) showing corresponding user interface displays in various states of operation. A first user interface display 431a (FIG. 4A) includes a display name 433a (i.e., “Rooms”). A selected group region 433b displays audio content information (e.g., artist name, track name, album art) of audio content played back in the selected group and/or zone. Group regions 433c and 433d display corresponding group and/or zone name, and audio content information audio content played back or next in a playback queue of the respective group or zone. An audio content region 433e includes information related to audio content in the selected group and/or zone (i.e., the group and/or zone indicated in the selected group region 433b). A lower display region 433f is configured to receive touch input to display one or more other user interface displays. For example, if a user selects “Browse” in the lower display region 433f, the control device 430 can be configured to output a second user interface display 431b (FIG. 4B) comprising a plurality of music services 433g (e.g., Spotify, Radio by Tunein, Apple Music, Pandora, Amazon, TV, local music, line-in) through which the user can browse and from which the user can select media content for play back via one or more playback devices (e.g., one of the playback devices 110 of FIG. 1A). Alternatively, if the user selects “My Sonos” in the lower display region 433f, the control device 430 can be configured to output a third user interface display 431c (FIG. 4C). A first media content region 433h can include graphical representations (e.g., album art) corresponding to individual albums, stations, or playlists. A second media content region 433i can include graphical representations (e.g., album art) corresponding to individual songs, tracks, or other media content. If the user selects a graphical representation 433j (FIG. 4C), the control device 430 can be configured to begin play back of audio content corresponding to the graphical representation 433j and output a fourth user interface display 431d that includes an enlarged version of the graphical representation 433j, media content information 433k (e.g., track name, artist, album), transport controls 433m (e.g., play, previous, next, pause, volume), and indication 433n of the currently selected group and/or zone name.

FIG. 5 is a schematic diagram of a control device 530 (e.g., a laptop computer, a desktop computer). The control device 530 includes transducers 534, a microphone 535, and a camera 536. A user interface 531 includes a transport control region 533a, a playback status region 533c, a playback zone region 533b, a playback queue region 533d, and a media content source region 533e. The transport control region comprises one or more controls for controlling media playback including, for example, volume, previous, play/pause, next, repeat, shuffle, track position, crossfade, equalization, etc. The audio content source region 533e includes a listing of one or more media content sources from which a user can select media items for play back and/or adding to a playback queue.

The playback zone region 533b can include representations of playback zones within the media playback system 100 (FIGS. 1A and 1B). In some embodiments, the graphical representations of playback zones may be selectable to bring up additional selectable icons to manage or configure the playback zones in the media playback system, such as a creation of bonded zones, creation of zone groups, separation of zone groups, renaming of zone groups, etc. In the illustrated embodiment, a “group” icon is provided within each of the graphical representations of playback zones. The “group” icon provided within a graphical representation of a particular zone may be selectable to bring up options to select one or more other zones in the media playback system to be grouped with the particular zone. Once grouped, playback devices in the zones that have been grouped with the particular zone can be configured to play audio content in synchrony with the playback device(s) in the particular zone. Analogously, a “group” icon may be provided within a graphical representation of a zone group. In the illustrated embodiment, the “group” icon may be selectable to bring up options to deselect one or more zones in the zone group to be removed from the zone group. In some embodiments, the control device 530 includes other interactions and implementations for grouping and ungrouping zones via the user interface 531. In certain embodiments, the representations of playback zones in the playback zone region 533b can be dynamically updated as playback zone or zone group configurations are modified.

The playback status region 533c includes graphical representations of audio content that is presently being played, previously played, or scheduled to play next in the selected playback zone or zone group. The selected playback zone or zone group may be visually distinguished on the user interface, such as within the playback zone region 533b and/or the playback queue region 533d. The graphical representations may include track title, artist name, album name, album year, track length, and other relevant information that may be useful for the user to know when controlling the media playback system 100 via the user interface 531.

The playback queue region 533d includes graphical representations of audio content in a playback queue associated with the selected playback zone or zone group. In some embodiments, each playback zone or zone group may be associated with a playback queue containing information corresponding to zero or more audio items for playback by the playback zone or zone group. For instance, each audio item in the playback queue may comprise a uniform resource identifier (URI), a uniform resource locator (URL) or some other identifier that may be used by a playback device in the playback zone or zone group to find and/or retrieve the audio item from a local audio content source or a networked audio content source, possibly for playback by the playback device. In some embodiments, for example, a playlist can be added to a playback queue, in which information corresponding to each audio item in the playlist may be added to the playback queue. In some embodiments, audio items in a playback queue may be saved as a playlist. In certain embodiments, a playback queue may be empty, or populated but “not in use” when the playback zone or zone group is playing continuously streaming audio content, such as Internet radio that may continue to play until otherwise stopped, rather than discrete audio items that have playback durations. In some embodiments, a playback queue can include Internet radio and/or other streaming audio content items and be “in use” when the playback zone or zone group is playing those items.

When playback zones or zone groups are “grouped” or “ungrouped,” playback queues associated with the affected playback zones or zone groups may be cleared or re-associated. For example, if a first playback zone including a first playback queue is grouped with a second playback zone including a second playback queue, the established zone group may have an associated playback queue that is initially empty, that contains audio items from the first playback queue (such as if the second playback zone was added to the first playback zone), that contains audio items from the second playback queue (such as if the first playback zone was added to the second playback zone), or a combination of audio items from both the first and second playback queues. Subsequently, if the established zone group is ungrouped, the resulting first playback zone may be re-associated with the previous first playback queue, or be associated with a new playback queue that is empty or contains audio items from the playback queue associated with the established zone group before the established zone group was ungrouped. Similarly, the resulting second playback zone may be re-associated with the previous second playback queue, or be associated with a new playback queue that is empty, or contains audio items from the playback queue associated with the established zone group before the established zone group was ungrouped.

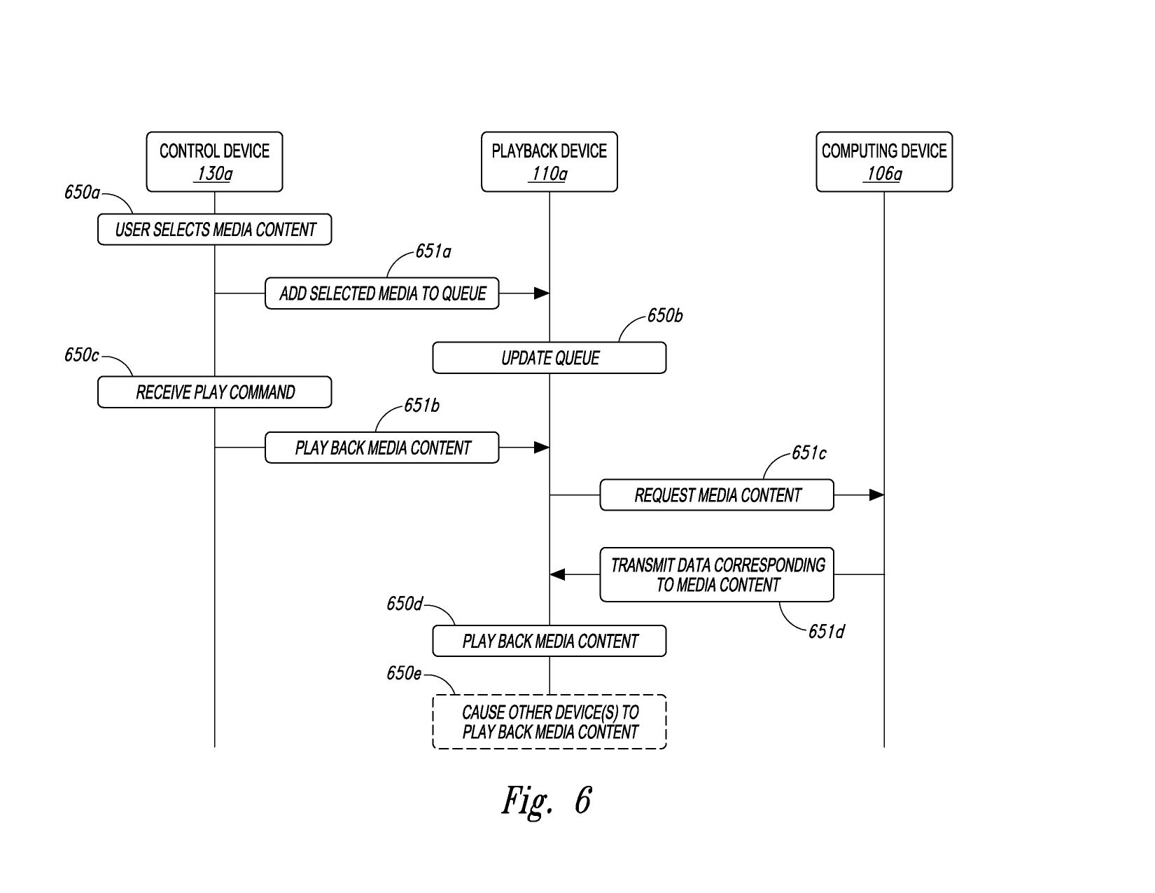

FIG. 6 is a message flow diagram illustrating data exchanges between devices of the media playback system 100 (FIGS. 1A-1M).

At step 650a, the media playback system 100 receives an indication of selected media content (e.g., one or more songs, albums, playlists, podcasts, videos, stations) via the control device 130a. The selected media content can comprise, for example, media items stored locally on one or more devices (e.g., the audio source 105 of FIG. 1C) connected to the media playback system and/or media items stored on one or more media service servers (one or more of the remote computing devices 106 of FIG. 1B). In response to receiving the indication of the selected media content, the control device 130a transmits a message 651a to the playback device 110a (FIGS. 1A-1C) to add the selected media content to a playback queue on the playback device 110a.

At step 650b, the playback device 110a receives the message 651a and adds the selected media content to the playback queue for play back.

At step 650c, the control device 130a receives input corresponding to a command to play back the selected media content. In response to receiving the input corresponding to the command to play back the selected media content, the control device 130a transmits a message 651b to the playback device 110a causing the playback device 110a to play back the selected media content. In response to receiving the message 651b, the playback device 110a transmits a message 651c to the computing device 106a requesting the selected media content. The computing device 106a, in response to receiving the message 651c, transmits a message 651d comprising data (e.g., audio data, video data, a URL, a URI) corresponding to the requested media content.

At step 650d, the playback device 110a receives the message 651d with the data corresponding to the requested media content and plays back the associated media content.

At step 650e, the playback device 110a optionally causes one or more other devices to play back the selected media content. In one example, the playback device 110a is one of a bonded zone of two or more players (FIG. 1M). The playback device 110a can receive the selected media content and transmit all or a portion of the media content to other devices in the bonded zone. In another example, the playback device 110a is a coordinator of a group and is configured to transmit and receive timing information from one or more other devices in the group. The other one or more devices in the group can receive the selected media content from the computing device 106a, and begin playback of the selected media content in response to a message from the playback device 110a such that all of the devices in the group play back the selected media content in synchrony.

### IV. Example Systems, Devices, and Methods for Generating a Wake on Audio Trigger

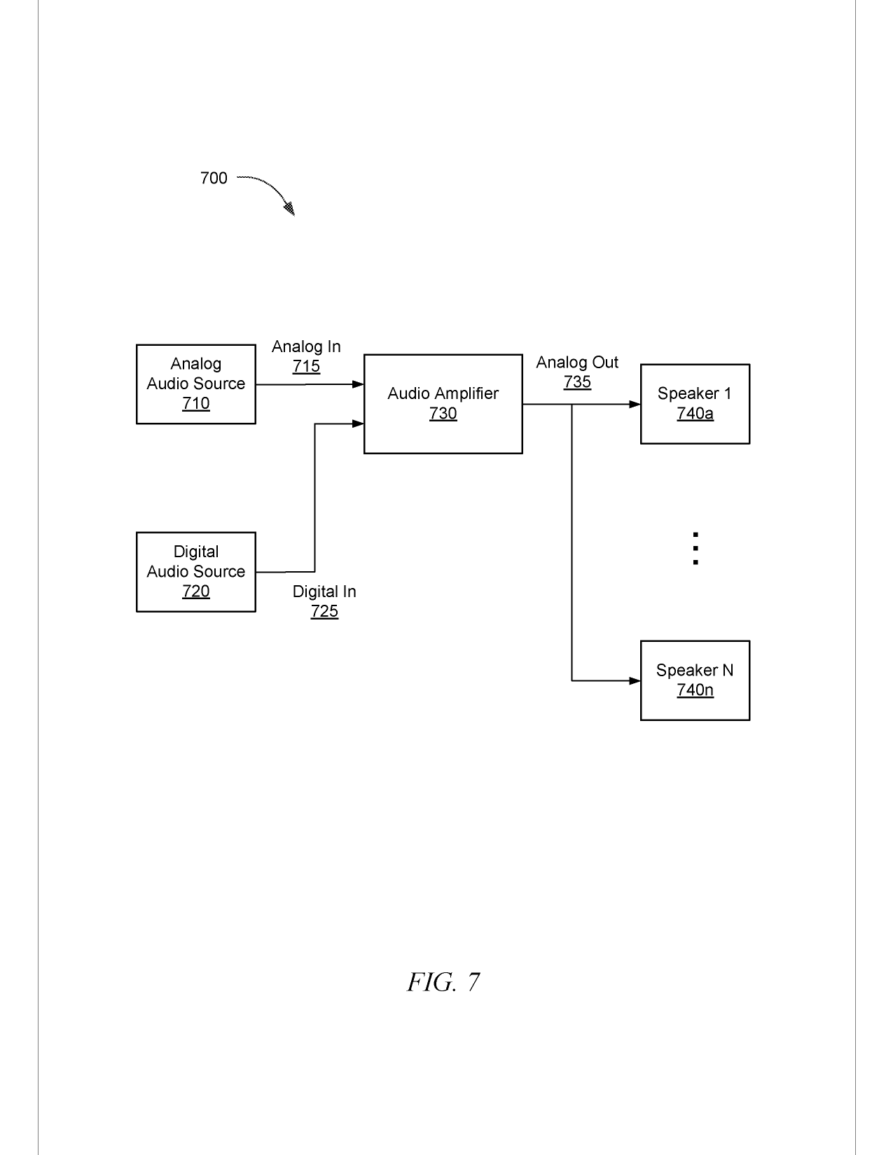

FIG. 7 illustrates an example of an audio playback environment 700. In some examples, the audio playback environment 700 may be part of a home theater or other residential environment in which it is desired to play back audio provided from an analog source such as a turntable or CD player. In some examples, the audio playback environment 700 may be part of a commercial environment such as a music venue, restaurant, bar, store, or shopping center, in which it is desired to play back audio provided from an analog source.

The audio playback environment 700 is shown to include an analog audio source 710, an audio amplifier 730, and one or more speakers 740. The audio amplifier 730 is configured to amplify an analog audio input signal 715 provided at an input port to generate an analog audio output signal 735 delivered at an output port at a desired power level to drive one or more speakers 740a, … 740n. For example, a bar may have a relatively large number of speakers distributed throughout the establishment (e.g., 50 or more), and the amplifier will provide analog audio at a suitable power level to drive those speakers.

In some embodiments, the audio amplifier 730 may be configured to accept analog audio input signal 715 from multiple analog audio sources with the ability to switch between different analog audio inputs.

In some instances, the audio amplifier 730 may also be configured to accept digital audio input 725 provided from one or more digital audio sources 720, for example over an HDMI link, a WI-FI link, a BLUETOOTH link. The audio amplifier 730 may then decode the digital audio input 725 and convert it to analog audio for analog amplification and distribution to speakers 740.

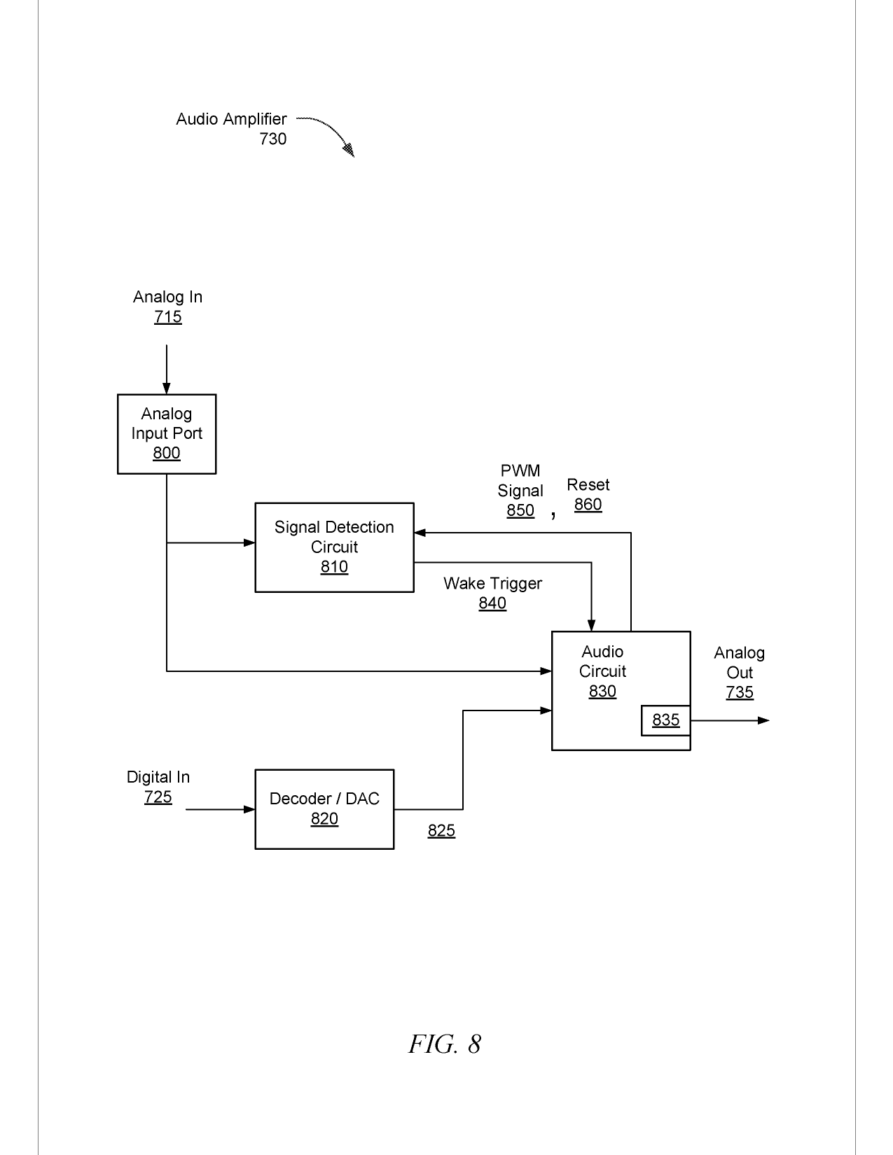

FIG. 8 is a block diagram of an example audio amplifier 730 configured in accordance with aspects of the disclosed technology. The audio amplifier is shown to include a signal detection circuit 810 and an audio circuit 830. In some embodiments, the audio circuit 830 is configured to amplify an analog audio signal which may be provided as an analog audio input signal 715 through an analog audio input port 800. In some instances, the audio amplifier may be configured to receive a digital audio input 725. In such instances, the audio amplifier may also include a decoder and DAC 820 which are configured to convert that digital signal to an analog audio signal 825 for amplification by audio circuit 830, which may include one or more components, such as an amplifier (e.g., an analog amplifier). In some examples, the audio circuitry 830 may be implemented in a single IC or multiple ICs that are, for example, communicatively coupled.

In some embodiments, the signal detection circuit 810 is configured to detect the presence of an audio signal at the analog input port 800. Although a cable may or may not be connected to the analog input port 800 at any given time, the fact that a cable is connected does not necessarily mean that a signal is present on that cable. Additionally, even if a signal is present, it may not be an audio signal. For example, the signal could be noise or a non-audio signal that is not of interest from an audio perspective. To this end, the signal detection circuit 810 is configured to detect an audio signal present at the analog audio input port 800 and generate a wake trigger 840 in response to that detection. In some examples, the wake trigger 840 serves to wake the audio circuit 830 from a power conserving sleep state to an awake state in which amplification of the audio signal may be performed to generate the analog audio output signal 735 at an output port 835. In some embodiments, for example when the audio amplifier 730 is configured to accept analog audio input from multiple analog audio sources, with the ability to switch between different analog audio input ports, the wake trigger 840 may be used to indicate which analog audio input port is active so that the amplifier can switch to that port.

In some examples, the wake trigger 840 may serve to wake the audio circuit 830 in an indirect manner. For example, the wake trigger 840 may feed to a power supply that provides the voltage for the supply rail of the audio circuit amplifier. In that instance, the wake trigger 840 causes the power supply to enable the DC output voltage to the amplifier supply rail, and that, in turn, causes the amplifier to “wake-up” and operate.

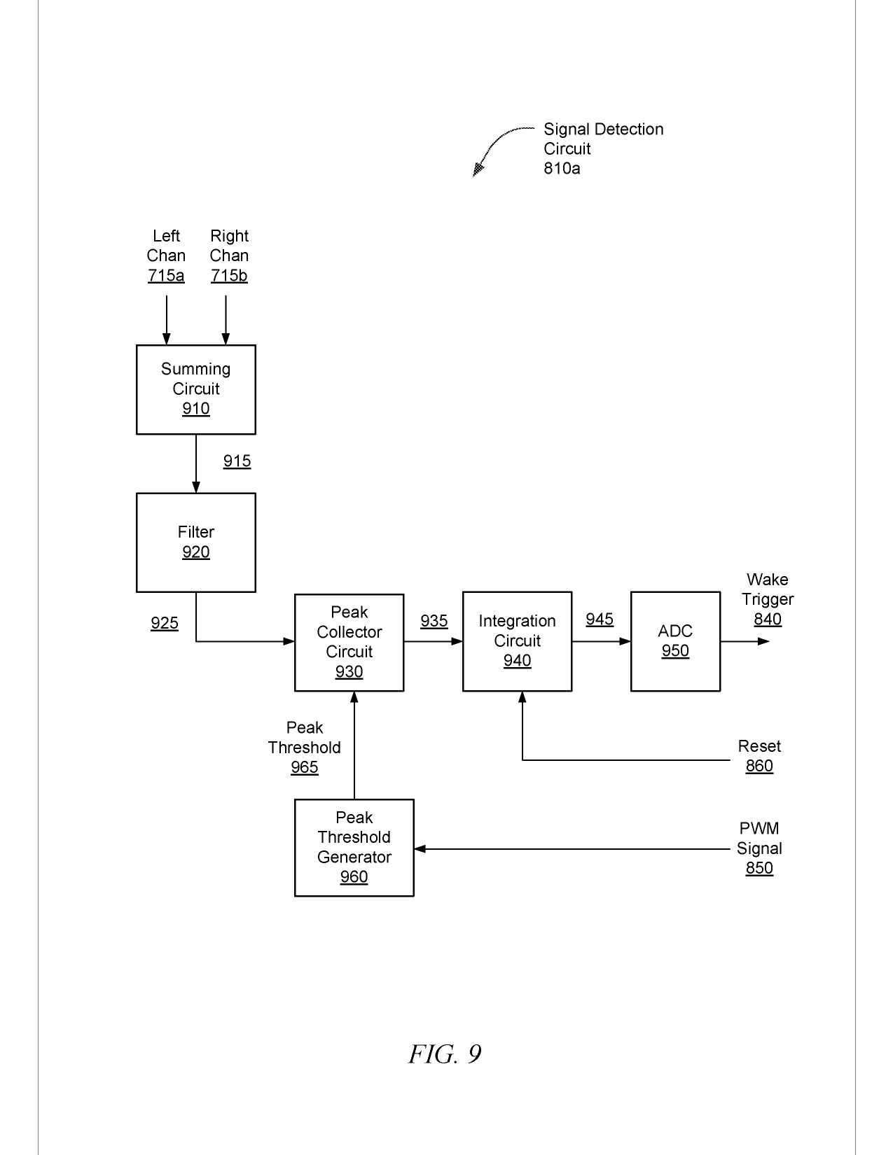

In some embodiments, the audio circuit 830 also generates pulsewidth modulation (PWM) signal 850 and reset signal 860 to control the signal detection circuit 810, as will be described below in connection with FIG. 9.

FIG. 9 is a block diagram of an example signal detection circuit 810a configured in accordance with aspects of the disclosed technology. Referring to FIG. 9, the signal detection circuit 810a is one example of signal detection circuit 810 and is shown to include a summing circuit 910, a filter 920, a peak collector circuit 930, an integration circuit 940, an analog-to-digital converter (ADC) 950, and a peak threshold generator circuit 960.

In some examples, the analog audio input signal 715 may be a multi-channel audio signal, for example, it may comprise a left channel 715a and a right channel 715b. In such cases, the analog input port may comprise a left channel port and a right channel port. The summing circuit 910 is configured to sum the left and right channels to create a single summed channel 915.

In some embodiments, the filter 920 is a bandpass filter circuit configured to filter the input signal (e.g., the summed signal within the channel 915) to a desired audio bandwidth to generate a filtered input signal 925. The bandpass filter 920 serves to reduce or eliminate noise and non-audio signals that lie outside of the audio bandwidth. In some examples, the audio bandwidth comprises frequencies in the range of 20 Hz and 20 kHz, which are frequencies that are audible to human listeners. In some embodiments, a low pass filter may be used as an alternative to a bandpass filter if noise and non-audio signals of concern are primarily in the higher frequency range (e.g., above 20 kHz).

In some embodiments, the peak collector circuit 930 is configured to compare the filtered input signal 925 to a peak threshold value 965. In some examples, the peak threshold value is dynamically adjustable and may be provided by the peak threshold generator circuit 960, as described below. The peak collector circuit 930 then generates a peak signal 935 comprising segments of the filtered input signal 925 that exceed the peak threshold value 965. This operation removes segments of the filtered input signal 925 that contain small voltage amplitude variations which are more likely to be associated with noise than audio.

In some embodiments, the integration circuit 940 is configured to integrate the peak signal 935 over a period of time to generate an analog trigger signal 945. In some examples, the time period is a window of selected duration to implement a moving average. The integration of the peak signal (e.g., the voltage amplitudes that are above the threshold 965) smooths out the peak signal 935 to provide a greater level of consistency in the analog trigger signal 945 which reduces false alarm triggers, for more reliable operation.

A reset signal 860 may be provided by the audio circuit 830 to reset the integration process. For example, the integrator may be reset back to a zero (or a near zero value) after a wake trigger is generated so that the audio circuit does not continue to receive wake triggers after audio has been detected and continues to be present. In some examples, the audio circuit may return to a sleep state after some period of time elapses during which no audio has been played. In this case, the reset signal may also be used to reinitialize the signal detector so that the audio circuit may again be triggered to an awake state when new audio is available at the analog input port.

The ADC 950 is configured to compare the analog trigger signal 945 to a detection threshold value and generate the digital wake trigger 840 when the analog trigger signal 945 exceeds the detection threshold value. The digital wake trigger 840 is transmitted to the audio circuit 830.

In some embodiments, the peak threshold generator circuit 960 is configured to generate the peak threshold 965 based on a signal 850 provided by the audio circuit 830, allowing for dynamic adjustment of the threshold. The dynamic threshold adjustment allows for adjustment of sensitivity to the input signal, for example to balance the tradeoff between the probability of detection of real audio being present at the input port versus the false alarm rate. In some embodiments, the signal 850 may be provided by the audio circuit 830 during an initialization period or upon power up, for example before the audio circuit has entered a sleep state. The signal 850 may also be provided or updated during subsequent awake states.

In some examples the signal 850 is a PWM threshold control signal. The peak threshold generator circuit 960 measures the duty cycle of PWM threshold control signal 850 to generate the peak threshold value 965 based on that measurement. In some examples, the PWM threshold control signal is a square wave having a clock frequency in the range of 23 MHz to 25 MHz with a duty cycle in the range of 5 percent to 95 percent. So, for example, a measured duty cycle of 5 percent may represent a lowest peak threshold value while a duty cycle of 95 percent may represent a highest peak threshold value within a range of desired peak threshold values.

In some embodiments, communication between the signal detection circuit 810 and the audio circuit 830 may be performed over a general purpose I/O (GPIO) bus. For example, the audio circuit 830 may be implemented, at least in part, as a system on a chip (SoC) comprising a plurality of GPIO pins including a first pin to receive the wake trigger 840 from the signal detection circuit 810, a second pin to propagate the PWM threshold control signal 850 to the signal detection circuit 810, and a third pin to propagate the integrator reset signal 860 to the signal detection circuit 810.

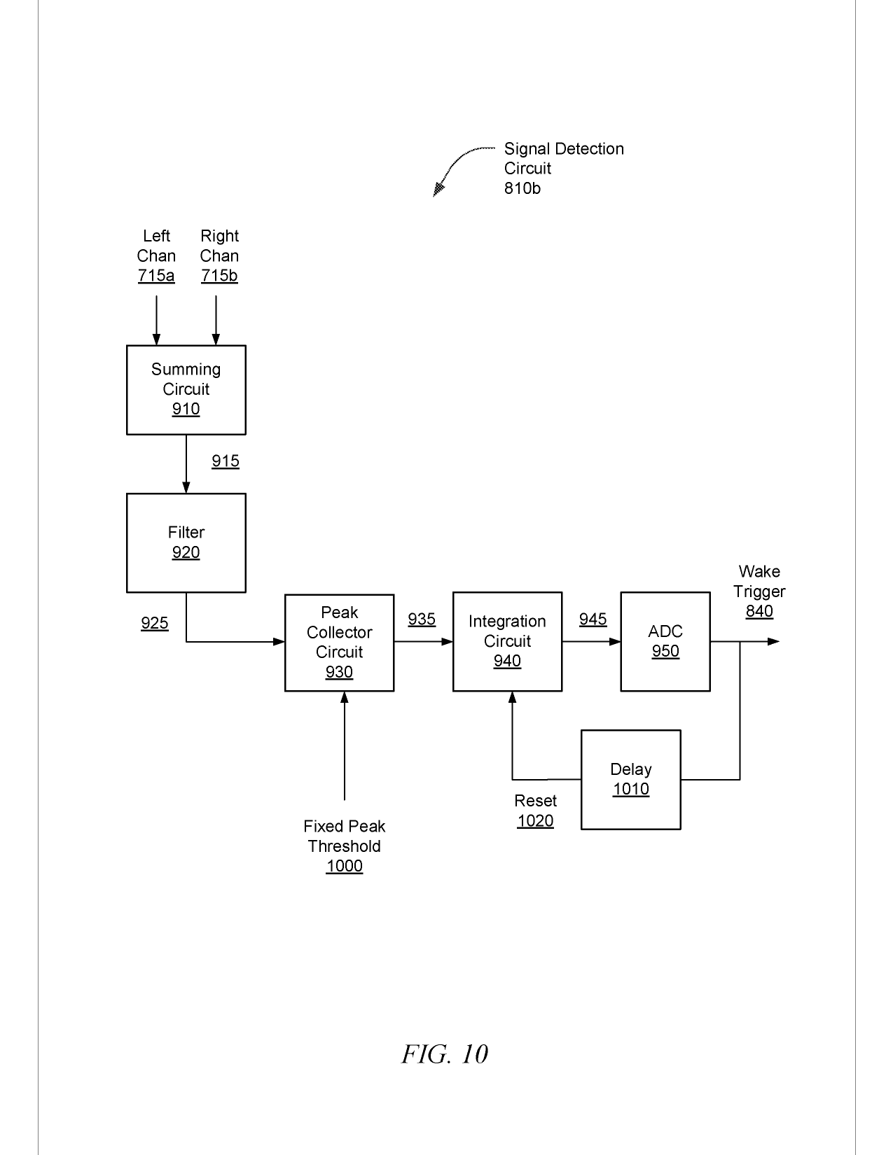

FIG. 10 is a block diagram of another example signal detection circuit 810b configured in accordance with aspects of the disclosed technology. Signal detection circuit 810b is similar to signal detection circuit 810a with the exception that the 810b embodiment eliminates the need for two of the GPIO pins: the pin for the integrator reset signal 860 and the pin for the PWM threshold control signal 850. Since the number of available pins on the GPIO bus may be limited, this embodiment provides an advantage by freeing up two of the pins for other purposes.

In this example, the PWM threshold control signal 850 and the peak threshold generator 960 are eliminated and, instead, a fixed peak threshold value 1000 is provided to the peak collector circuit 930. In some examples, the fixed peak threshold value 1000 may be generated by a voltage dividing resistor network.

Additionally, in this example, a signal delay circuit or delay element 1010 is employed to provide a time delayed version of the wake trigger 840 as an integrator reset signal 1020. So, for example, after the wake trigger 840 has been generated and provided to the audio circuit 830 for a selected period of time (as determined by the delay circuit 1010), the integration circuit 940 can be reset.

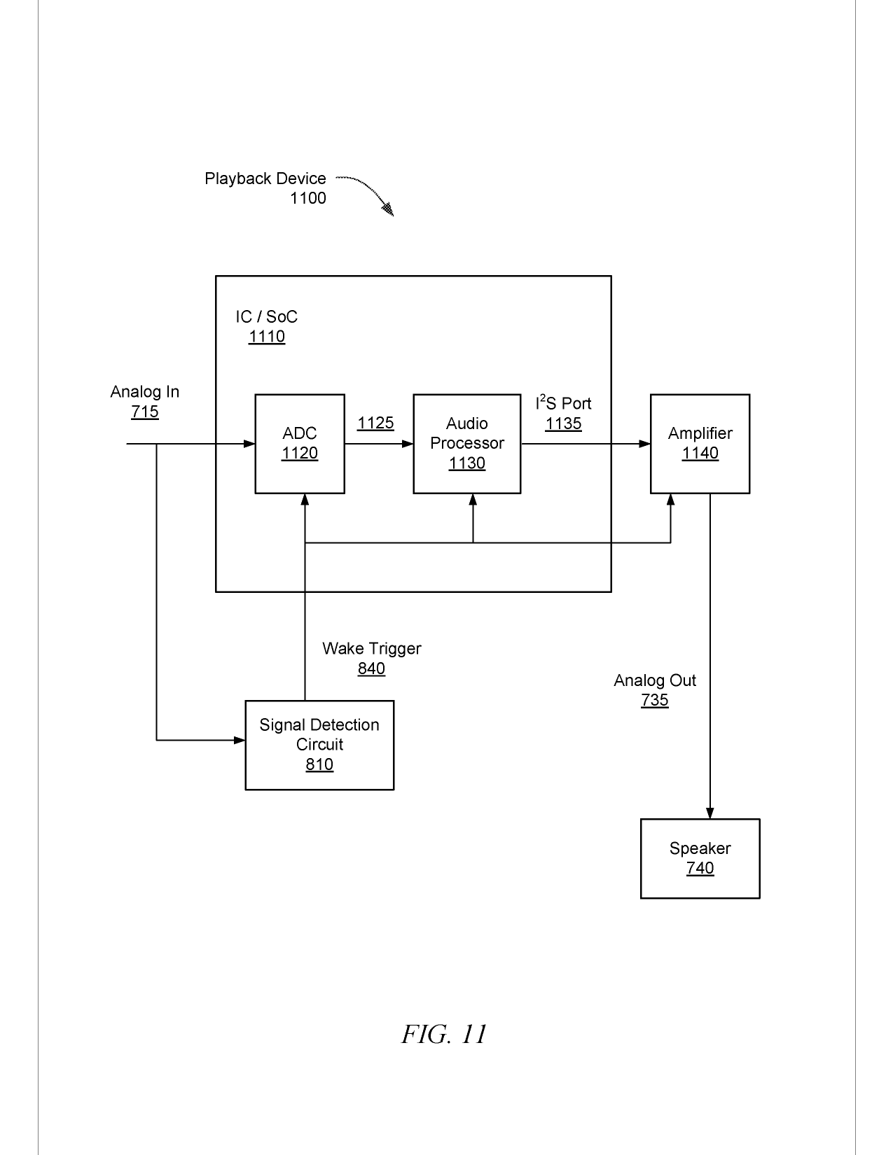

FIG. 11 is a block diagram of an example playback device 1100 configured in accordance with aspects of the disclosed technology. In this example, the playback device 1100 is configured to perform audio processing in the digital domain and to provide energy efficient operation by transitioning from a sleep state to an awake state based on a wake trigger 840 provided by signal detection circuit 810.

The playback device may comprise an integrated circuit or SoC 1110 and is shown to include an ADC 1120 and an audio processor 1130. Additionally, the playback device 1100 may comprise one or more other components coupled to the SoC 1110 including, for example, a signal detection circuit 810 and amplifier 1140. The ADC 1120 is configured to convert the analog input signal 715 to a digital signal 1125 which is provided to the audio processor 1130. In some examples, the audio processor 1130 is configured to perform any suitable processing, including digital signal processing techniques, on the digitized audio 1125. In some examples, the processed audio may then be transmitted over an inter-IC sound (I2S) bus 1135 to the amplifier 1140 which converts the processed audio to an amplified analog audio signal 735 to be played out through speakers 740.

Signal detection circuit 810 functions as previously described, for example in implementations 810a or 810b described above. In particular, when an audio signal is detected to be present in the analog input signal 715, the signal detection circuit generates the wake trigger 840 which may cause one or more of the other components of the playback device 1100 to transition from a sleep state to an awake state. In some examples, the signal detection circuit 810 may be configured to wake-up the main SoC 1110 which can then cause the main SoC to perform additional functions such as: enabling the amplifier (directly or indirectly via a power supply for the amplifier) and processing the audio received at the analog input 715.

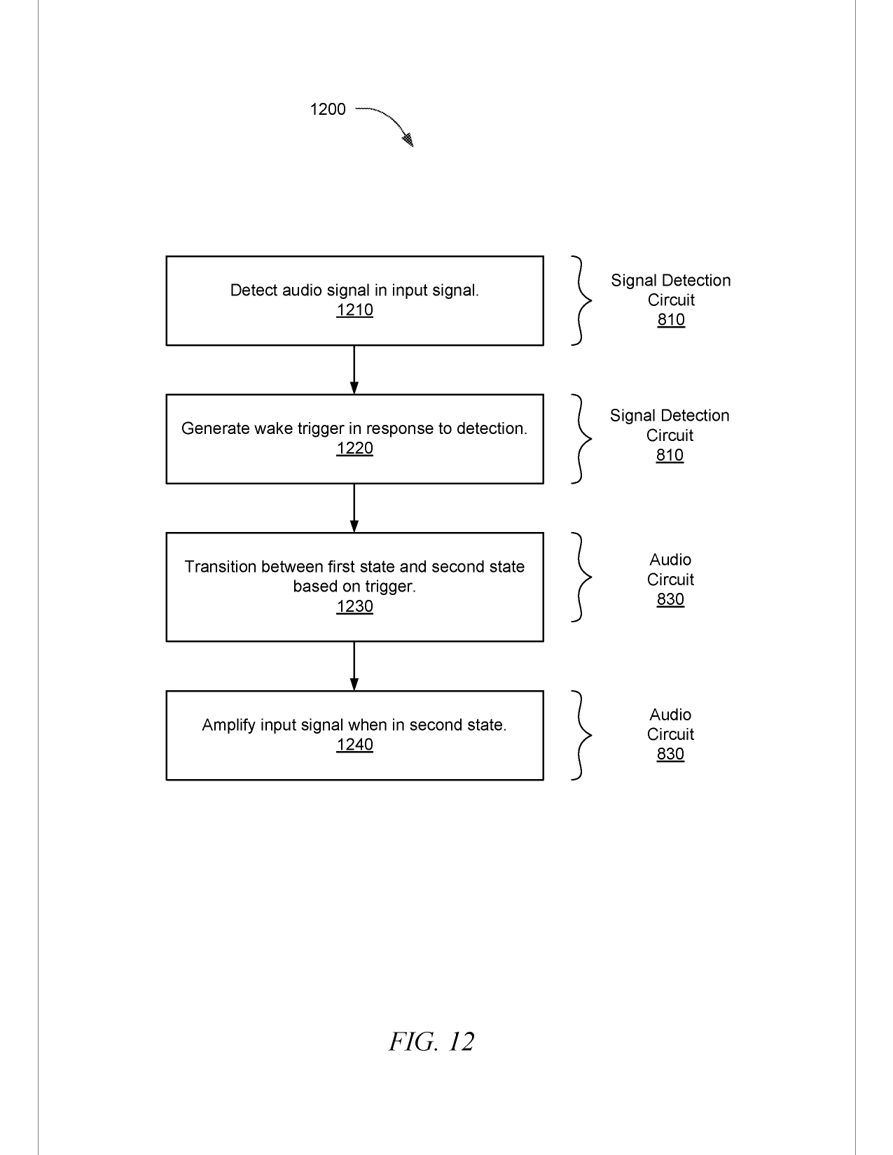

FIG. 12 is a flowchart illustrating an example method 1200 for generating a wake on audio trigger. As discussed previously, energy efficient operation is important to reduce the carbon emissions associated with operation of an electronic device over its lifetime. One technique for increasing energy efficiency of an audio device is to allow the device to remain in a lower power state during periods when there is no audio signal present, and then waking the device from that state in response to the detection of an audio signal. Method 1200, for operating an audio device, can be implemented by an audio amplifier or playback device disclosed herein (e.g., amplifier 730 or playback device 1100).

Method 1200 commences at block 1210, which includes detecting an audio signal present in an input signal presented at an analog audio input port of the audio amplifier. In some embodiments, detecting the audio signal includes: (1) filtering the input signal to an audio bandwidth to generate a filtered input signal; (2) comparing the filtered input signal to a peak threshold value; (3) generating a peak signal comprising segments of the filtered input signal that exceed the peak threshold value; (4) integrating the peak signal over a period of time to generate an analog trigger signal; and (5) detecting that the analog trigger signal exceeds a detection threshold value.

At block 1220, the method 1200 further includes generating a wake trigger to be transmitted to the audio circuit in response to the detection of the audio signal.

At block 1230, the method 1200 further includes transitioning between a first state and a second state based on the trigger. In some examples, the first state is a sleep state, and the second state is an awake state, such that the audio amplifier consumes less power in the first state than the second state.

At block 1240, the method 1200 further includes amplifying the input signal, when in the second state, so that the amplified signal may be used to drive one or more speakers.

In some embodiments, generating the trigger more generally includes integrating the input signal over a period of time and detecting that the integrated input signal exceeds a threshold value. In some examples, the integration is performed on a portion of the input signal that exceeds a first threshold value over a period of time and the trigger is generated by detecting that the integrated portion of the input signal exceeds a second threshold value. In some embodiments, the thresholds are application specific voltage thresholds that are based on the voltage levels produced by, for example, the analog audio sources (e.g., the turntable, the CD player, etc.).

### V. Conclusion

The above discussions relating to playback devices, controller devices, playback zone configurations, and media content sources provide only some examples of operating environments within which functions and methods described herein may be implemented. Other operating environments and configurations of media playback systems, playback devices, and network devices not explicitly described herein may also be applicable and suitable for implementation of the functions and methods.

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways to implement such systems, methods, apparatus, and/or articles of manufacture.

Additionally, references herein to “embodiment” means that a particular feature, structure, or characteristic described in connection with the embodiment can be included in at least one example embodiment of an invention. The appearances of this phrase in various places in the specification are not necessarily all referring to the same embodiment, nor are separate or alternative embodiments mutually exclusive of other embodiments. As such, the embodiments described herein, explicitly and implicitly understood by one skilled in the art, can be combined with other embodiments.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain embodiments of the present disclosure can be practiced without certain, specific details. In other instances, well known methods, procedures, components, and circuitry have not been described in detail to avoid unnecessarily obscuring aspects of the embodiments. Accordingly, the scope of the present disclosure is defined by the appended claims rather than the foregoing description of embodiments.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

### VII. Example Features

The following examples pertain to further embodiments, from which numerous permutations and configurations will be apparent.

(Feature 1) A device comprising: an analog audio input port; an audio amplifier configured to transition between a first state and a second state based on a trigger, and amplify, when in the second state, an input signal present at the analog audio input port; and a signal detection circuit coupled to the analog audio input port and configured to detect an audio signal present in the input signal and generate the trigger when the audio signal is detected.

(Feature 2) The device of feature 1, wherein the audio amplifier consumes less power in the first state than the second state.

(Feature 3) The device of feature 2, wherein the first state is a sleep state and the second state is an awake state.

(Feature 4) The device of feature 1, wherein to generate the trigger comprises to integrate the input signal over a period of time and to detect that the integrated input signal exceeds a threshold value.

(Feature 5) The device of feature 1, wherein to generate the trigger comprises to integrate a portion of the input signal that exceeds a first threshold value over a period of time and to detect that the integrated portion of the input signal exceeds a second threshold value.

(Feature 6) The device of feature 1, wherein the signal detection circuit comprises: a first circuit configured to filter the input signal to an audio bandwidth to generate a filtered input signal; a second circuit configured to compare the filtered input signal to a peak threshold value and generate a peak signal comprising segments of the filtered input signal that exceed the peak threshold value; and a third circuit configured to integrate the peak signal over a period of time to generate an analog trigger signal.

(Feature 7) The device of feature 6, wherein the signal detection circuit further comprises an analog-to-digital converter configured to convert the analog trigger signal to the trigger.

(Feature 8) The device of feature 6, wherein the analog audio input port comprises a left channel port and a right channel port, and the signal detection circuit further comprises a summing circuit configured to sum a first input signal present at the left channel port with a second input signal present at the right channel port to generate the input signal.

(Feature 9) The device of feature 6, wherein the signal detection circuit further comprises a peak threshold generator configured to measure a duty cycle of a pulsewidth modulated (PWM) threshold control signal and generate the peak threshold value based on a measurement of the duty cycle.

(Feature 10) The device of feature 9, wherein the PWM threshold control signal is a square wave at a clock frequency in a range of 23 MHz to 25 MHz, and the duty cycle is in a range of 5 percent to 95 percent.

(Feature 11) The device of feature 9, wherein the audio amplifier includes a system on a chip (SoC) comprising a plurality of general purpose input/output (GPIO) pins including a first pin to receive the trigger and a second pin to propagate the PWM threshold control signal.

(Feature 12) The device of feature 11, wherein the plurality of GPIO pins includes a third pin to propagate an integrator reset signal and the integration circuit is configured to reset in response to receipt of the integrator reset signal from the SoC on the third pin.

(Feature 13) The device of feature 6, wherein the first circuit is a band pass filter circuit configured to propagate signals between 20 Hz and 20 kHz.

(Feature 14) The device of feature 6, wherein the signal detection circuit further comprises a delay circuit configured to provide a delayed version of the trigger and wherein the integration circuit is configured to reset in response to the delayed version of the trigger.

(Feature 15) The device of feature 6, wherein the signal detection circuit further comprises a voltage dividing resistor network configured to generate the peak threshold value.

(Feature 16) The device of feature 1, further comprising an analog audio output port configured to transmit the amplified input signal to a speaker.

(Feature 17) A playback device comprising: an integrated circuit (IC) comprising at least one processor; an analog audio input port coupled to the IC; an audio amplifier; a signal detection circuit coupled to the analog audio input port and the IC, the signal detection circuit configured to detect an audio signal present in an input signal present at the analog audio input port and generate a trigger when the audio signal is detected; and at least one non-transitory computer-readable medium comprising program instructions that are executable by the at least one processor such that the playback device is configured to: based on detection of the trigger, transition from a first state to a second state; and after the transition from the first state to the second state, play back the audio signal received at the analog audio input port.

(Feature 18) The playback device of feature 17, wherein the playback device consumes less power in the first state than the second state.

(Feature 19) The playback device of feature 18, wherein the first state is a sleep state and the second state is an awake state.

(Feature 20) The playback device of feature 17, wherein to generate the trigger comprises to integrate the input signal over a period of time and to detect that the integrated input signal exceeds a threshold value.

(Feature 21) The playback device of feature 17, wherein to generate the trigger comprises to integrate a portion of the input signal that exceeds a first threshold value over a period of time and to detect that the integrated portion of the input signal exceeds a second threshold value.

(Feature 22) The playback device of feature 17, wherein the signal detection circuit comprises: a first circuit configured to filter the input signal to an audio bandwidth to generate a

filtered input signal; a second collector circuit configured to compare the filtered input signal to a peak threshold value and generate a peak signal comprising segments of the filtered input signal that exceed the peak threshold value; and a third circuit configured to integrate the peak signal over a period of time to generate an analog trigger signal.

(Feature 23) The playback device of feature 22, wherein the signal detection circuit further comprises an analog-to-digital converter configured to convert the analog trigger signal to the trigger.

(Feature 24) The playback device of feature 22, wherein the analog audio input port comprises a left channel port and a right channel port, and the signal detection circuit further comprises a summing circuit configured to sum a first input signal present at the left channel port with a second input signal present at the right channel port to generate the input signal.

(Feature 25) The playback device of feature 22, wherein the signal detection circuit further comprises a peak threshold generator configured to measure a duty cycle of a pulsewidth modulated (PWM) threshold control signal and generate the peak threshold value based on a measurement of the duty cycle.

(Feature 26) The playback device of feature 25, wherein the PWM threshold control signal is a square wave at a clock frequency in a range of 23 MHz to 25 MHz, and the duty cycle is in a range of 5 percent to 95 percent.

(Feature 27) The playback device of feature 22, wherein the first circuit is a band pass filter circuit configured to propagate signals between 20 Hz and 20 kHz.

(Feature 28) The playback device of feature 22, wherein the signal detection circuit further comprises a delay circuit configured to provide a delayed version of the trigger and wherein the integration circuit is configured to reset in response to the delayed version of the trigger.

(Feature 29) The playback device of feature 22, wherein the signal detection circuit further comprises a voltage dividing resistor network configured to generate the peak threshold value.

(Feature 30) A method for operating an audio amplifier, the method comprising: detecting an audio signal present in an input signal present at an analog audio input port of the audio

amplifier; generating a trigger when the audio signal is detected; transitioning between a first state and a second state based on the trigger; and amplifying, when in the second state, the input signal.

(Feature 31) The method of feature 30, wherein the audio amplifier consumes less power in the first state than the second state.

(Feature 32) The method of feature 31, wherein the first state is a sleep state and the second state is an awake state.

(Feature 33) The method of feature 30, wherein to generate the trigger comprises to integrate the input signal over a period of time and to detect that the integrated input signal exceeds a threshold value.

(Feature 34) The method of feature 30, wherein to generate the trigger comprises to integrate a portion of the input signal that exceeds a first threshold value over a period of time and to detect that the integrated portion of the input signal exceeds a second threshold value.

(Feature 35) The method of feature 30, further comprising: filtering the input signal to an audio bandwidth to generate a filtered input signal; comparing the filtered input signal to a peak threshold value; generating a peak signal comprising segments of the filtered input signal that exceed the peak threshold value; and integrating the peak signal over a period of time to generate an analog trigger signal.

(Feature 36) The method of feature 35, further comprising converting the analog trigger signal to the trigger.

(Feature 37) The method of feature 35, further comprising summing a first input signal present at a left channel port of the analog audio input port with a second input signal present at a right channel port of the analog audio input port to generate the input signal.

(Feature 38) The method of feature 35, further comprising measuring a duty cycle of a pulsewidth modulated (PWM) threshold control signal and generating the peak threshold value based on a measurement of the duty cycle.

(Feature 39) The method of feature 38, wherein the PWM threshold control signal is a square wave at a clock frequency in a range of 23 MHz to 25 MHz, and the duty cycle is in a range of 5 percent to 95 percent.

(Feature 40) The method of feature 35, further comprising resetting the integration circuit in response to a delayed version of the trigger.

(Feature 41) The method of feature 30, further comprising transmitting the amplified input signal to a speaker.

What is claimed is:

1. A device comprising:
an analog audio input port;
an audio amplifier configured to
transition between a first state and a second state based on a trigger, and
amplify, when in the second state, an input signal present at the analog audio input port; and
a signal detection circuit coupled to the analog audio input port and configured to detect an audio signal present in the input signal and generate the trigger when the audio signal is detected.

2. The device of claim 1, wherein the audio amplifier consumes less power in the first state than the second state and wherein the first state is a sleep state, and the second state is an awake state.

3. The device of claim 1, wherein to generate the trigger comprises to integrate the input signal over a period of time and to detect that the integrated input signal exceeds a threshold value.

4. The device of claim 1, wherein to generate the trigger comprises to integrate a portion of the input signal that exceeds a first threshold value over a period of time and to detect that the integrated portion of the input signal exceeds a second threshold value.

5. The device of claim 1, wherein the signal detection circuit comprises:
a first circuit configured to filter the input signal to an audio bandwidth to generate a filtered input signal;
a second circuit configured to compare the filtered input signal to a peak threshold value and generate a peak signal comprising segments of the filtered input signal that exceed the peak threshold value; and
a third circuit configured to integrate the peak signal over a period of time to generate an analog trigger signal.

6. The device of claim 5, wherein the analog audio input port comprises a left channel port and a right channel port, and the signal detection circuit further comprises a summing circuit configured to sum a first input signal present at the left channel port with a second input signal present at the right channel port to generate the input signal.

7. The device of claim 5, wherein the signal detection circuit further comprises a peak threshold generator configured to measure a duty cycle of a pulsewidth modulated (PWM) threshold control signal and generate the peak threshold value based on a measurement of the duty cycle, and wherein the PWM threshold control signal is a square wave at a clock frequency in a range of 23 MHz to 25 MHz, and the duty cycle is in a range of 5 percent to 95 percent.

8. The device of claim 7, wherein the audio amplifier includes a system on a chip (SoC) comprising a plurality of general purpose input/output (GPIO) pins including a first pin to receive the trigger and a second pin to propagate the PWM threshold control signal.

9. The device of claim 8, wherein the plurality of GPIO pins includes a third pin to propagate an integrator reset signal and the integration circuit is configured to reset in response to receipt of the integrator reset signal from the SoC on the third pin.

10. The device of claim 5, wherein the first circuit is a band pass filter circuit configured to propagate signals between 20 Hz and 20 kHz and the signal detection circuit further comprises a delay circuit configured to provide a delayed version of the trigger and wherein the integration circuit is configured to reset in response to the delayed version of the trigger.

11. The device of claim 5, wherein the signal detection circuit further comprises a voltage dividing resistor network configured to generate the peak threshold value.

12. The device of claim 1, further comprising an analog audio output port configured to transmit the amplified input signal to a speaker.

13. A playback device comprising:
an integrated circuit (IC) comprising at least one processor;
an analog audio input port coupled to the IC;
an audio amplifier;
a signal detection circuit coupled to the analog audio input port and the IC, the signal detection circuit configured to detect an audio signal present in an input signal present at the analog audio input port and generate a trigger when the audio signal is detected; and
at least one non-transitory computer-readable medium comprising program instructions that are executable by the at least one processor such that the playback device is configured to:
based on detection of the trigger, transition from a first state to a second state; and
after the transition from the first state to the second state, play back the audio signal received at the analog audio input port.

14. The playback device of claim 13, wherein the playback device consumes less power in the first state than the second state and wherein the first state is a sleep state and the second state is an awake state.

15. The playback device of claim 13, wherein to generate the trigger comprises to integrate the input signal over a period of time and to detect that the integrated input signal exceeds a threshold value.

16. The playback device of claim 13, wherein to generate the trigger comprises to integrate a portion of the input signal that exceeds a first threshold value over a period of time and to detect that the integrated portion of the input signal exceeds a second threshold value.

17. A method for operating an audio amplifier, the method comprising:
detecting an audio signal present in an input signal present at an analog audio input port of the audio amplifier;
generating a trigger when the audio signal is detected;
transitioning between a first state and a second state based on the trigger; and
amplifying, when in the second state, the input signal.

18. The method of claim 17, wherein the audio amplifier consumes less power in the first state than the second state, and wherein the first state is a sleep state, and the second state is an awake state.

19. The method of claim 17, wherein to generate the trigger comprises to integrate the input signal over a period of time and to detect that the integrated input signal exceeds a threshold value.

20. The method of claim 17, wherein to generate the trigger comprises to integrate a portion of the input signal that exceeds a first threshold value over a period of time and to detect that the integrated portion of the input signal exceeds a second threshold value.
